(19) United States
(12) Patent Application Publication
(10) Pub. No.: US 2024/0310728 A1
(43) Pub. Date: Sep. 19, 2024

(54) PHOTOSENSITIVE COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Takashi KAWASHIMA, Haibara-gun (JP); Kazuya OOTA, Haibara-gun (JP)

(73) Assignee: FUJIFILM Corporation, Tokyo (JP)

(21) Appl. No.: 18/667,601

(22) Filed: May 17, 2024

Related U.S. Application Data
(63) Continuation of application No. PCT/JP2022/045385, filed on Dec. 9, 2022.

(30) Foreign Application Priority Data
Dec. 17, 2021 (JP) 2021-204678

(51) Int. Cl. G03F 7/031

(52) U.S. Cl. CPC G03F 7/031

(57) ABSTRACT

Provided are a photosensitive composition containing a colorant A including a pigment, a pigment derivative B, and a resin C, in which the colorant A includes a blue pigment, the pigment derivative B includes a transparent pigment derivative B1 and a chromatic pigment derivative B2, and a total content of the colorant A and the pigment derivative B in a total solid content of the photosensitive composition is 40% by mass or more; a film formed of the photosensitive composition; a color filter; a solid-state imaging element; and an image display device.

### CROSS-REFERENCE TO RELATED APPLICATIONS

This application is a Continuation of PCT International Application No. PCT/JP2022/045385 filed on Dec. 9, 2022, which claims priority under 35 U.S.C § 119(a) to Japanese Patent Application No. 2021-204678 filed on Dec. 17, 2021. Each of the above application(s) is hereby expressly incorporated by reference, in its entirety, into the present application.

### BACKGROUND OF THE INVENTION

### 1. Field of the Invention

The present invention relates to a photosensitive composition containing a blue pigment. The present invention further relates to a film formed of the photosensitive composition, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

The color filter is manufactured by using a photosensitive composition containing a colorant. In addition, in a case where a pigment is used as the colorant, the pigment is generally dispersed in the photosensitive composition by using a pigment derivative, a resin, or the like.

JP2019-133154A discloses an invention relating to a photosensitive composition containing a pigment, a predetermined coloring agent derivative having a triazine structure, a predetermined resin type dispersant, a polymerizable monomer, a photopolymerization initiator, a resin binder, and a solvent.

### SUMMARY OF THE INVENTION

A film formed of a photosensitive composition containing a blue pigment tends to be discolored by irradiation with light. In recent years, further improvement in light resistance has been required for the film used in a color filter or the like, and further improvement in light resistance has also been desired for the film formed of a photosensitive composition containing a blue pigment.

In addition, in recent years, further improvement in moisture resistance has been required for the film used for a color filter or the like.

Therefore, an object of the present invention is to provide a photosensitive composition with which a film having excellent light resistance and moisture resistance can be formed. In addition, an object of the present invention is to provide a film, a color filter, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A photosensitive composition comprising:
a colorant A including a pigment;
a pigment derivative B; and
a resin C,
in which the colorant A includes a blue pigment,
the pigment derivative B includes a transparent pigment derivative B1 and a chromatic pigment derivative B2, and
a total content of the colorant A and the pigment derivative B in a total solid content of the photosensitive composition is 40% by mass or more.

<2> The photosensitive composition according to <1>,
in which a maximum value of a molar absorption coefficient of the pigment derivative B1 in a wavelength range of 400 to 700 nm is 3,000 L·mol⁻¹·cm⁻¹ or less.

<3> The photosensitive composition according to <1> or <2>,
in which a maximum value of a molar absorption coefficient of the pigment derivative B2 in a wavelength range of 400 to 700 nm is 10,000 L·mol⁻¹·cm⁻¹ or more.

<4> The photosensitive composition according to any one of <1> to <3>,
in which the pigment derivative B1 is a compound having a triazine ring.

<5> The photosensitive composition according to any one of <1> to <4>,
in which the pigment derivative B1 is a compound including a group represented by Formula (A1),

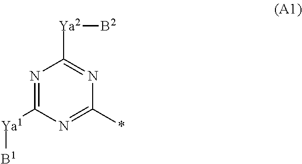

in Formula (A1), * represents a bonding site,
Ya¹ and Ya² each independently represent —N(Ra¹)- or —O—, where Ra¹ represents a hydrogen atom, an alkyl group, an alkenyl group, an alkynyl group, or an aryl group, and
B¹ and B² each independently represent a hydrogen atom or a substituent.

<6> The photosensitive composition according to any one of <1> to <5>,
in which the pigment derivative B2 is a phthalocyanine compound.

<7> The photosensitive composition according to any one of <1> to <6>,
in which a maximal absorption wavelength of the pigment derivative B2 is in a wavelength range of 400 to 700 nm.

<8> The photosensitive composition according to any one of <1> to <7>,
in which the blue pigment is a phthalocyanine compound.

<9> The photosensitive composition according to any one of <1> to <8>,
in which the colorant A includes the blue pigment and a violet pigment.

<10> The photosensitive composition according to any one of <1> to <9>, further comprising:
a polymerizable monomer; and
a photopolymerization initiator.

<11> The photosensitive composition according to any one of <1> to <10>,
in which, in a case where a film having a film thickness of 1 μm is formed of the photosensitive composition, an average value of a transmittance of the film in a thickness direction to light in a wavelength range of 400 to 500 nm is 55% or more, an average value of a transmittance of the film in the thickness direction to light in a wavelength range of 600 to 700 nm is 20% or less, and a wavelength at which a transmittance is 50% is in a wavelength range of 450 to 550 nm.

<12> The photosensitive composition according to any one of <1> to <11>,
in which the photosensitive composition is a photosensitive composition for forming a blue pixel.

<13> A film obtained from the photosensitive composition according to any one of <1> to <12>.

<14> A color filter comprising:
the film according to <13>.

<15> A solid-state imaging element comprising:
the film according to <13>.

<16> An image display device comprising:
the film according to <13>.

According to the present invention, it is possible to provide a photosensitive composition with which a film having excellent light resistance and moisture resistance can be formed, a film, a color filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, symbols (for example, A, B, C, and the like) added before or after the name are terms used to distinguish the constitutional components, and the type of the constitutional components, the number of constitutional components, and the superiority or inferiority of the constitutional components are not limited.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a colorant which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, the term “step” is not only an independent step, but also includes a step which is not clearly distinguished from other steps in a case where an intended action of the step is obtained.

### <Photosensitive Composition>

The photosensitive composition according to the embodiment of the present invention contains a colorant A including a pigment, a pigment derivative B, and a resin C, in which the colorant A includes a blue pigment, the pigment derivative B includes a transparent pigment derivative B1 and a chromatic pigment derivative B2, and a total content of the colorant A and the pigment derivative B in a total solid content of the photosensitive composition is 40% by mass or more.

With the photosensitive composition according to the embodiment of the present invention, a film having excellent light resistance and moisture resistance can be formed. The reason for obtaining such an effect is presumed as follows.

Since the photosensitive composition according to the embodiment of the present invention contains the transparent pigment derivative B1, it is presumed that, in a case where a photosensitive composition layer is formed on a support using the photosensitive composition, and this photosensitive composition layer is exposed and cured, it is easy to transmit light to a deep portion (support side) of the photosensitive composition layer by the exposure. Therefore, it is presumed that a film which is sufficiently cured by the exposure can be formed. In addition, since the photosensitive composition according to the embodiment of the present invention further contains the chromatic pigment derivative B2 in addition to the transparent pigment derivative B1, it is presumed that, even in a case where the film after being formed is irradiated with light, the pigment derivative B2 appropriately absorbs the light to suppress decomposition, denaturation, or the like of the resin, the colorant, and the like. Therefore, it is presumed that a film having excellent light resistance can be formed with the photosensitive composition according to the embodiment of the present invention.

In addition, since the photosensitive composition according to the embodiment of the present invention contains the transparent pigment derivative B1 in addition to the chromatic pigment derivative B2, it is presumed that, even in a case where a film formed of the photosensitive composition is exposed to a high humidity environment and decomposition or modification of the pigment derivative occurs, influence of a spectral variation due to the decomposition or modification of the pigment derivative can be reduced, and thus a film having excellent moisture resistance can be formed.

In addition, the photosensitive composition according to the embodiment of the present invention also has excellent storage stability. Since the photosensitive composition according to the embodiment of the present invention contains two or more kinds of the pigment derivatives, it is presumed that a network of pigment-pigment derivative-resin is easily formed in the photosensitive composition, and aggregation of the pigment is suppressed, and as a result, the storage stability of the photosensitive composition can be improved.

A blue hue is a color tone having a high transmittance in the vicinity of a wavelength of 400 to 500 nm, and is a color tone in which the influence on spectrum due to yellowing of the resin or the like is extremely large. Since the film formed of the photosensitive composition according to the embodiment of the present invention can suppress yellowing due to irradiation with light, the photosensitive composition according to the embodiment of the present invention can be preferably used as a photosensitive composition for forming a blue pixel.

The photosensitive composition according to the embodiment of the present invention is preferably used as a photosensitive composition for a color filter. Specifically, the photosensitive composition according to the embodiment of the present invention can be preferably used as a photosensitive composition for forming a blue pixel of a color filter.

In a case where a film having a film thickness of 1 μm is formed of the photosensitive composition according to the embodiment of the present invention, it is preferable that an average value of a transmittance of this film in a thickness direction to light in a wavelength range of 400 to 500 nm is 55% or more, an average value of a transmittance of this film in the thickness direction to light in a wavelength range of 600 to 700 nm is 20% or less, and a wavelength at which a transmittance is 50% is in a wavelength range of 450 to 550 nm. The photosensitive composition satisfying such spectral characteristics can be preferably used as a photosensitive composition for forming a blue pixel.

The average value of the transmittance of the above-described film to light in a wavelength range of 400 to 500 nm is preferably 60% or more, and more preferably 70% or more.

The average value of the transmittance of the above-described film to light in a wavelength range of 600 to 700 nm is preferably 15% or less, and more preferably 10% or less.

The wavelength at which the transmittance of the above-described film is 50% is preferably in a wavelength range of 460 to 540 nm, and more preferably in a wavelength range of 470 to 520 nm.

A concentration of solid contents of the photosensitive composition according to the embodiment of the present invention is preferably 5% to 30% by mass. The lower limit is preferably 7.5% by mass or more and more preferably 10% by mass or more. The upper limit is preferably 25% by mass or less, more preferably 20% by mass or less, and still more preferably 15% by mass or less.

Hereinafter, each of the components used in the photosensitive composition according to the embodiment of the present invention will be described.

### <<Colorant A>>

The photosensitive composition according to the embodiment of the present invention contains a colorant A (hereinafter, also referred to as a colorant). In the present invention, a pigment is used as the colorant.

A content of the pigment in the colorant contained in the photosensitive composition is preferably 20% to 100% by mass, more preferably 30% to 100% by mass, and still more preferably 40% to 100% by mass.

It is also preferable that the colorant contained in the photosensitive composition is substantially only the pigment. The case in which the colorant contained in the photosensitive composition is substantially only the pigment means that the content of the pigment in the colorant is 99% by mass or more, and the content thereof is preferably 99.9% by mass or more and more preferably 100% by mass.

The colorant contained in the photosensitive composition may include a pigment and a dye. In a case where the pigment and the dye are used in combination, an amount of the dye is preferably 2 to 300 parts by mass with respect to 100 parts by mass of the blue pigment. The upper limit thereof is preferably 200 parts by mass or less and more preferably 100 parts by mass or less. The lower limit is preferably 5 parts by mass or more and more preferably 10 parts by mass or more.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersibility of the pigment in the photosensitive composition is good. The primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter of the pigment in the present specification is an arithmetic average value of primary particle diameters of primary particles of 400 pigments. In addition, the primary particle of the pigment refers to a particle which is independent without aggregation.

For the pigment, a crystal grain size obtained from a half-width of a peak derived from any crystal plane in the X-ray diffraction spectrum, in a case where CuKα ray is used as an X-ray source, is preferably 0.1 nm to 100 nm, more preferably 0.5 nm to 50 nm, still more preferably 1 nm to 30 nm, and particularly preferably 5 nm to 25 nm.

The colorant contained in the photosensitive composition according to the embodiment of the present invention includes a blue pigment. Examples of the blue pigment include a phthalocyanine pigment and a triarylmethane pigment, and a phthalocyanine pigment is preferable. Specific examples of the blue pigment include Color Index (C. I.) Pigment Blue 1, 2, 15, 15:1, 15:2, 15:3, 15:4, 15:6, 16, 22, 29, 60, 64, 66, 79, 80, 87, and 88. In addition, an aluminum phthalocyanine pigment having a phosphorus atom can also be used as the blue pigment. Specific examples thereof include the compounds described in paragraph Nos. 0022 to 0030 of JP2012-247591A and paragraph No. 0047 of JP2011-157478A.

A content of the blue pigment in the colorant contained in the photosensitive composition is preferably 5% by mass or more, more preferably 8% by mass or more, still more preferably 10% by mass or more, even more preferably 20% by mass or more, even still more preferably 30% by mass or more, and particularly preferably 50% by mass or more. The upper limit thereof may be 100% by mass or less, 80% by mass or less, or 60% by mass or less.

It is preferable that the colorant is a colorant further including a violet pigment. That is, the colorant preferably includes the blue pigment and a violet pigment. According to this aspect, it is easy to form a film having a hue suitable for blue color spectrum. In addition, in a case where the blue pigment and the violet pigment are used in combination in the related art, there is a tendency that spectral characteristics derived from the violet pigment are likely to fluctuate due to irradiation with light. However, with the photosensitive composition according to the embodiment of the present invention, even in a case where the blue pigment and the violet pigment are used in combination, variation in spectral characteristics due to the irradiation with light can be suppressed, and a film having excellent light resistance can be formed.

Examples of the violet pigment include a xanthene pigment, a quinacridone pigment, a dioxazine pigment, and a benzimidazolone pigment, and a xanthene pigment or a dioxazine pigment is preferable. Specific examples of the violet pigment include C. I. Pigment Violet 1, 19, 23, 27, 32, 37, 42, 60, and 61.

A content of the violet pigment is preferably 2 to 100 parts by mass with respect to 100 parts by mass of the blue pigment. The upper limit thereof is preferably 80 parts by mass or less and more preferably 60 parts by mass or less. The lower limit thereof is preferably 3 parts by mass or more, more preferably 5 parts by mass or more, still more preferably 10 parts by mass or more, and particularly preferably 20 parts by mass or more.

In addition, the total content of the blue pigment and the violet pigment in the colorant contained in the photosensitive composition is preferably 5% by mass or more, more preferably 10% by mass or more, still more preferably 20% by mass or more, even more preferably 30% by mass or more, even still more preferably 50% by mass or more, and particularly preferably 70% by mass or more. The upper limit thereof may be 100% by mass or less, 90% by mass or less, or 80% by mass or less.

The colorant contained in the photosensitive composition is preferably substantially only the blue pigment and the violet pigment. The case in which the colorant contained in the photosensitive composition is substantially only the blue pigment and the violet pigment means that the total content of the blue pigment and the violet pigment in the colorant is 99% by mass or more, and the total content thereof is preferably 99.9% by mass or more and more preferably 100% by mass.

The colorant can further contain a pigment having a hue other than the blue pigment and the violet pigment (hereinafter, also referred to as other pigments). Examples of the other pigments include a yellow pigment, an orange pigment, a red pigment, and a green pigment. Specific examples of these pigments include the following pigments.

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232, 233, 234, 235, and 236 (all of which are yellow pigments);
C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);
C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297 (all of which are red pigments); and
C. I. Pigment Green 7, 10, 36, 37, 58, 59, 62, 63, 64, 65, and 66 (all of which are green pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A. In addition, as the green pigment, compounds described in CN2010-6909027A, phthalocyanine compounds described in WO2012/102395A, which have phosphoric acid ester as a ligand, phthalocyanine compounds described in JP2019-008014A, phthalocyanine compounds described in JP2018-180023A, compounds described in JP2019-038958A, aluminum phthalocyanine compounds described in JP2020-070426A, core-shell type coloring agents described in JP2020-076995A, and the like can also be used.

In addition, as the yellow pigment, an azobarbiturate nickel complex having the following structure can also be used.

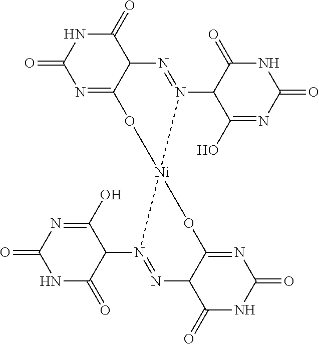

In addition, as the yellow pigment, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765B (JP-S48-032765B), quinophthalone compounds described in JP2019-008014A, quinophthalone compounds described in JP6607427B, compounds described in KR10-2014-0034963A, compounds described in JP2017-095706A, compounds described in TW2019-20495A, compounds described in JP6607427B, compounds described in JP2020-033525A, compounds described in JP2020-033524A, compounds described in JP2020-033523A, compounds described in JP2020-033522A, compounds described in JP2020-033521A, compounds described in WO2020/045200A, compounds described in WO2020/045199A, compounds described in WO2020/045197A, azo compounds described in JP2020-093994A, perylene compounds described in JP2020-083982A, perylene compounds described in WO2020/105346A, and quinophthalone compounds described in JP2020-517791A can also be used.

As the red pigment, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, brominated diketopyrrolopyrrole compounds described in JP2020-085947A, naphtholazo compounds described in JP2012-229344A, red pigments described in JP6516119B, red pigments described in JP6525101B, brominated diketopyrrolopyrrole compounds described in paragraph No. 0229 of JP2020-090632A, anthraquinone compounds described in KR10-2019-0140741A, anthraquinone compounds described in KR10-2019-0140744A, perylene compounds described in JP2020-079396A, diketopyrrolopyrrole compounds described in paragraph Nos. 0025 to 0041 of JP2020-066702A, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

A content of the other pigments in the colorant contained in the photosensitive composition is preferably 20% by mass or less, more preferably 10% by mass or less, still more preferably 5% by mass or less, and particularly preferably 1% by mass or less.

A dye can also be used as the colorant. Examples of the dye include a pyrazoleazo dye, an anilinoazo dye, a triarylmethane dye, an anthraquinone dye, an anthrapyridone dye, a benzylidene dye, an oxonol dye, a pyrazolotriazoleazo dye, a pyridoneazo dye, a cyanine dye, a phenothiazine dye, a pyrrolopyrazoleazomethine dye, a xanthene dye, a phthalocyanine dye, a benzopyran dye, an indigo dye, and a pyrromethane dye. From the reason that a film having a hue suitable for blue color spectrum is easily formed, the dye used in the present invention is preferably a blue dye or a violet dye. In addition, the dye is preferably a xanthene dye or a triarylmethane dye.

As the colorant, diarylmethane compounds described in JP2020-504758A, triarylmethane dye polymers described in KR10-2020-0028160A, xanthene compounds described in JP2020-117638A, phthalocyanine compounds described in WO2020/174991A, isoindoline compounds or salts thereof described in JP2020-160279A, a compound represented by Formula 1, described in KR10-2020-0069442A, a compound represented by Formula 1, described in KR10-2020-0069730A, a compound represented by Formula 1, described in KR10-2020-0069070A, a compound represented by Formula 1, described in KR10-2020-0069067A, a compound represented by Formula 1, described in KR10-2020-0069062A, halogenated zinc phthalocyanine pigments described in JP6809649B, or isoindoline compounds described in JP2020-180176A can be used. The chromatic colorant may be rotaxane, the coloring agent skeleton may be used in a cyclic structure of the rotaxane, may be used in a rod-like structure, or may be used in both structures.

In addition, the total solid content of the colorant A and the pigment derivative B in the total solid content of the photosensitive composition is 40% by mass or more, preferably 42% by mass or more, more preferably 45% by mass or more, and still more preferably 47% by mass or more. The upper limit thereof is preferably 85% by mass or less, more preferably 80% by mass or less, and still more preferably 70% by mass or less.

In addition, the content of the pigment in the total solid content of the photosensitive composition is preferably 20% by mass or more, more preferably 25% by mass or more, and still more preferably 30% by mass or more. The upper limit thereof is preferably 80% by mass or less, more preferably 70% by mass or less, and still more preferably 60% by mass or less.

In addition, the content of the blue pigment in the total solid content of the photosensitive composition is preferably 5% by mass or more, more preferably 8% by mass or more, and still more preferably 10% by mass or more. The upper limit thereof is preferably 80% by mass or less, more preferably 70% by mass or less, and still more preferably 60% by mass or less.

In addition, the content of the blue pigment and the violet pigment in the total solid content of the photosensitive composition is preferably 10% by mass or more, more preferably 15% by mass or more, still more preferably 20% by mass or more, even more preferably 25% by mass or more, and particularly preferably 30% by mass or more. The upper limit thereof is preferably 80% by mass or less, more preferably 70% by mass or less, and still more preferably 60% by mass or less.

### <<Pigment Derivative B>>

The photosensitive composition according to the embodiment of the present invention contains a pigment derivative B (hereinafter, also referred to as a pigment derivative). The pigment derivative used in the photosensitive composition according to the embodiment of the present invention includes a transparent pigment derivative B1 and a chromatic pigment derivative B2.

### (Pigment Derivative B1)

The maximum value of a molar absorption coefficient of the pigment derivative B1 in a wavelength range of 400 to 700 nm is preferably 3,000 L·mol⁻¹·cm⁻¹ or less, more preferably 1,000 L·mol⁻¹·cm⁻¹ or less, and still more preferably 100 L·mol⁻¹·cm⁻¹ or less. The lower limit of the maximum value of the molar absorption coefficient described above is, for example, 1 L·mol⁻¹·cm⁻¹ or more and may be 10 L·mol⁻¹·cm⁻¹ or more.

It is also preferable that the pigment derivative B1 satisfies any one of the following spectral characteristics (a) to (d).
(a) maximum value of the molar absorption coefficient in a wavelength range of more than 700 nm and 750 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.
(b) maximum value of the molar absorption coefficient in a wavelength range of more than 750 nm and 800 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.
(c) maximum value of the molar absorption coefficient in a wavelength range of more than 800 nm and 850 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.
(d) maximum value of the molar absorption coefficient in a wavelength range of more than 850 nm and 900 nm or less is preferably 3,000 L·mol⁻¹·cm⁻¹ or less, more preferably 1,000 L·mol⁻¹·cm⁻¹ or less, and still more preferably 100 L·mol⁻¹·cm⁻¹ or less.

The pigment derivative B1 preferably includes an aromatic ring. The aromatic ring may be an aromatic hydrocarbon ring or an aromatic heterocyclic ring. In addition, the aromatic ring may be a single ring or a fused ring. Specifically, as the aromatic ring, an aromatic ring selected from a benzene ring, a naphthalene ring, a fluorene ring, a perylene ring, an imidazole ring, a pyrazole ring, an oxazole ring, a thiazole ring, an imidazoline ring, a pyridine ring, a triazole ring, an imidazoline ring, a pyrazine ring, a pyrimidine ring, a pyridazine ring, a quinoline ring, an isoquinoline ring, a quinoxaline ring, a quinazoline ring, a benzimidazole ring, a benzopyrazole ring, a benzoxazole ring, a benzothiazole ring, a benzotriazole ring, an indole ring, an isoindole ring, a triazine ring, a pyrrole ring, a carbazole ring, a benzimidazolinone ring, a phthalimide ring, a phthalocyanine ring, an anthraquinone ring, a diketopyrrolopyrrole ring, an isoindolinone ring, an isoindoline ring, and a quinacridone ring; a fused ring including these aromatic rings; or the like is preferable. The above-described fused ring may be an aromatic ring or a non-aromatic ring as a whole, but is preferably an aromatic ring. In addition, the pigment derivative B1 may have only one aromatic ring or fused ring, but for the reason that, as the number of aromatic rings increases, pigment adsorbability is improved by π-π interaction, and it is easy to suppress the aggregation of the pigment in the film, it is preferable to have two or more of these rings. The above-described aromatic ring or fused ring may further have a substituent. Examples of the substituent include the substituent T described later.

The pigment derivative B1 is more preferably a compound having a nitrogen-containing aromatic heterocyclic ring, and still more preferably a compound having a triazine ring. The pigment derivative B1 is particularly preferably a compound having a group represented by Formula (A1).

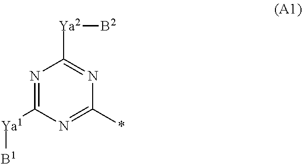

In Formula (A1), * represents a bonding site,
Ya¹ and Ya² each independently represent —N(Ra¹)- or —O—, where Ra¹ represents a hydrogen atom, an alkyl group, an alkenyl group, an alkynyl group, or an aryl group, and
B¹ and B² each independently represent a hydrogen atom or a substituent.

Ya¹ and Ya² in Formula (A1) each independently represent —N(Ra¹)- or —O—, and from the reason that the effects of the present invention are more easily obtained remarkably, —N(Ra¹)- is more preferable.

Ra¹ represents a hydrogen atom, an alkyl group, an alkenyl group, an alkynyl group, or an aryl group, and a hydrogen atom or an alkyl group is preferable and a hydrogen atom is more preferable.

The alkyl group represented by Ra¹ preferably has 1 to 20 carbon atoms, more preferably has 1 to 15 carbon atoms, and still more preferably has 1 to 8 carbon atoms. The alkyl group may be any of linear, branched, and cyclic forms, and is preferably linear or branched and more preferably linear. The alkyl group represented by Ra¹ may further have a substituent. Examples of the substituent include the substituent T described later.

The alkenyl group represented by Ra¹ preferably has 2 to 20 carbon atoms, more preferably has 2 to 12 carbon atoms, and still more preferably has 2 to 8 carbon atoms. The alkenyl group may be any of linear, branched, and cyclic forms, and is preferably linear or branched and more preferably linear. The alkenyl group represented by Ra¹ may further have a substituent. Examples of the substituent include the substituent T described later.

The alkynyl group represented by Ra¹ preferably has 2 to 40 carbon atoms, more preferably has 2 to 30 carbon atoms, and still more preferably has 2 to 25 carbon atoms. The alkynyl group may be any of linear, branched, and cyclic forms, and is preferably linear or branched and more preferably linear. The alkynyl group represented by Ra¹ may further have a substituent. Examples of the substituent include the substituent T described later.

The aryl group represented by Ra¹ preferably has 6 to 30 carbon atoms, more preferably has 6 to 20 carbon atoms, and still more preferably has 6 to 12 carbon atoms. The aryl group represented by Ra¹ may further have a substituent. Examples of the substituent include the substituent T described later.

B¹ and B² in Formula (A1) each independently represent a hydrogen atom or a substituent. Examples of the substituent include the substituent T described later, and an alkyl group, an aryl group, or a heterocyclic group is preferable, an aryl group or a heterocyclic group is more preferable, and an aryl group is still more preferable. In addition, from the reason that color unevenness can be more easily suppressed, at least one of B¹ or B² is also preferably a heterocyclic group. The heterocyclic group is preferably a nitrogen-containing heterocyclic group and more preferably a benzimidazolone group.

The alkyl group, aryl group, and heterocyclic group represented by B¹ and B² may further have a substituent. Examples of the further substituent include an alkyl group (preferably an alkyl group having 1 to 30 carbon atoms), a fluoroalkyl group (preferably a fluoroalkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably an acyl group having 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably a heteroarylthio group having 1 to 30 carbon atoms), an alkylsulfonyl group (preferably an alkylsulfonyl group having 1 to 30 carbon atoms), an arylsulfonyl group (preferably an arylsulfonyl group having 6 to 30 carbon atoms), a heteroarylsulfonyl group (preferably a heteroarylsulfonyl group having 1 to 30 carbon atoms), an alkylsulfinyl group (preferably an alkylsulfinyl group having 1 to 30 carbon atoms), an arylsulfinyl group (preferably an arylsulfinyl group having 6 to 30 carbon atoms), a heteroarylsulfinyl group (preferably a heteroarylsulfinyl group having 1 to 30 carbon atoms), a ureido group (preferably a ureido group having 1 to 30 carbon atoms), a phosphoric acid amide group (preferably a phosphoric acid amide group having 1 to 30 carbon atoms), a hydroxyl group, a carboxyl group, a sulfo group, a phosphoric acid group, a mercapto group, a halogen atom, a cyano group, an alkylsulfino group, an arylsulfino group, a hydrazino group, and an imino group. Among these, an alkyl group, a fluoroalkyl group, an alkoxy group, an amino group, a halogen atom, an alkenyl group, a hydroxyl group, an alkoxycarbonyl group, an acyloxy group, an acylamino group, or a nitro group is preferable.

The above-described substituent may be an acid group or a basic group. The acid group is preferably at least one selected from a carboxyl group, a sulfo group, a phosphoric acid group, or a salt thereof, and more preferably at least one selected from a carboxyl group, a sulfo group, or a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. The basic group is preferably at least one selected from an amino group, a pyridyl group, salts thereof, a salt of an ammonium group, or a phthalimidomethyl group, more preferably at least one selected from an amino group, a salt of an amino group, or a salt of an ammonium group, and more preferably an amino group or a salt of an amino group. Examples of the amino group include —NH₂, a dialkylamino group, an alkylarylamino group, a diarylamino group, and a cyclic amino group. The dialkylamino group, alkylarylamino group, diarylamino group, and cyclic amino group may further have a substituent. Examples of the substituent include the above-described substituent T. Examples of an atom or atomic group constituting the salts include a hydroxide ion, a halogen ion, a carboxylate ion, a sulfonate ion, and a phenoxide ion.

It is also preferable that the alkyl group, aryl group, and heterocyclic group represented by B¹ and B² do not have the above-described further substituent.

### (Substituent T)

Examples of a substituent T include a halogen atom, a cyano group, a nitro group, an alkyl group, an alkenyl group, an alkynyl group, an aryl group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, an alkyl group, an alkenyl group, an alkynyl group, an aryl group, or a heteroaryl group. Rt¹ and Rt² may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, and still more preferably has 1 to 8 carbon atoms. The alkyl group may be any of linear, branched, and cyclic forms, and is preferably linear or branched and more preferably linear.

The alkenyl group preferably has 2 to 30 carbon atoms, more preferably has 2 to 12 carbon atoms, and particularly preferably has 2 to 8 carbon atoms. The alkenyl group may be any of linear, branched, and cyclic forms, and is preferably linear or branched and more preferably linear.

The alkynyl group preferably has 2 to 30 carbon atoms and more preferably has 2 to 25 carbon atoms. The alkynyl group may be any of linear, branched, and cyclic forms, and is preferably linear or branched and more preferably linear.

The aryl group preferably has 6 to 30 carbon atoms, more preferably has 6 to 20 carbon atoms, and still more preferably has 6 to 12 carbon atoms.

The heterocyclic group may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The alkyl group, the alkenyl group, the alkynyl group, the aryl group, and the heterocyclic group may have a substituent or may be unsubstituted. Examples of the substituent include the substituents described as the substituent T described above.

Specific examples of the aromatic ring included in the pigment derivative B1 include groups having the following structures and groups having structures which are shown as specific examples of Z¹ described later. In the following structural formulae, Me represents a methyl group.

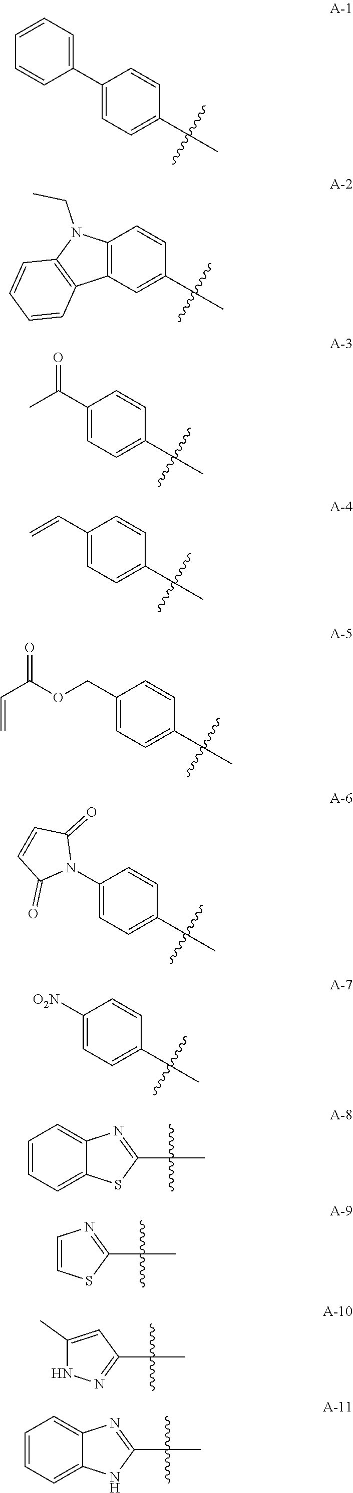

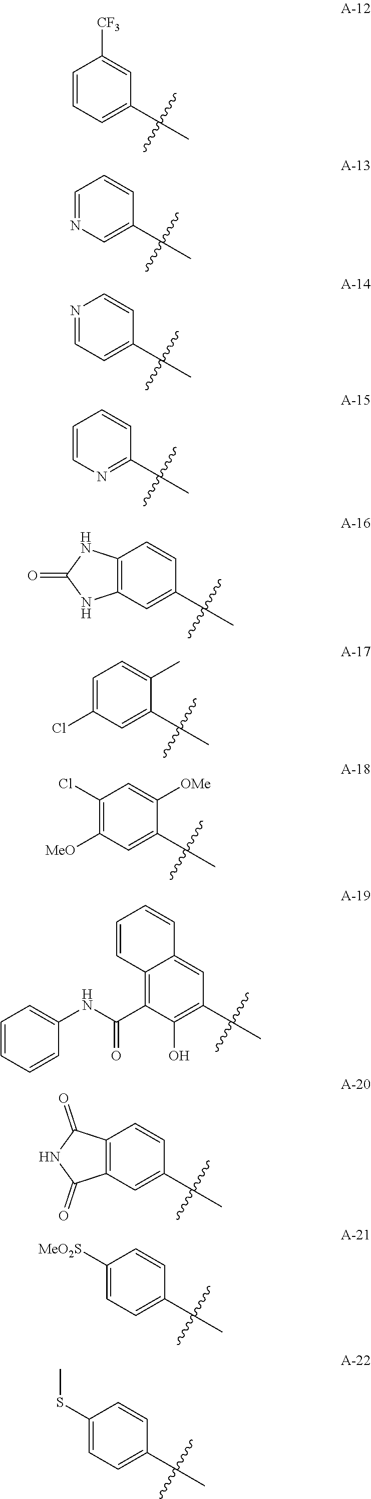

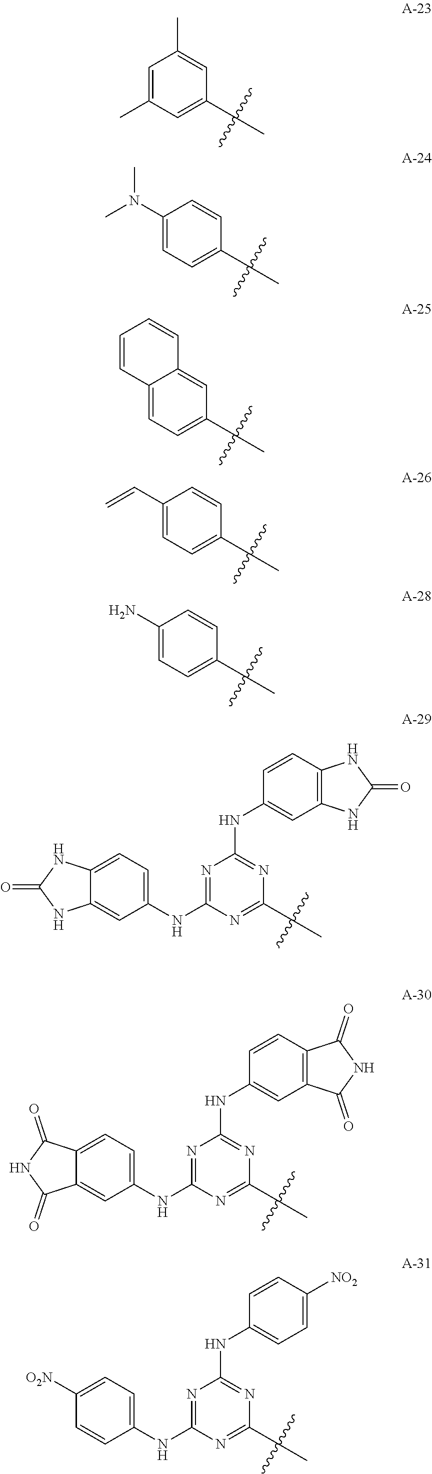

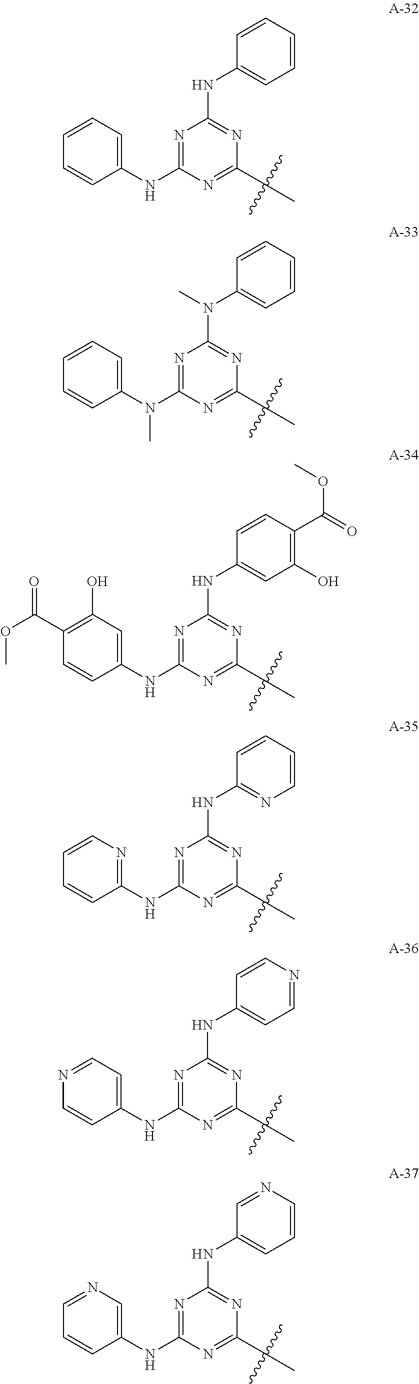 [SMILES: *c1nc(Nc2ccccc2)nc(Nc2ccccc2)n1 ; *c1nc(N(C)c2ccccc2)nc(N(C)c2ccccc2)n1 ; *c1nc(Nc2ccc(C(=O)OC)c(O)c2)nc(Nc2ccc(C(=O)OC)c(O)c2)n1 ; *c1nc(Nc2ccccn2)nc(Nc2ccccn2)n1 ; *c1nc(Nc2ccncc2)nc(Nc2ccncc2)n1 ; *c1nc(Nc2cccnc2)nc(Nc2cccnc2)n1]

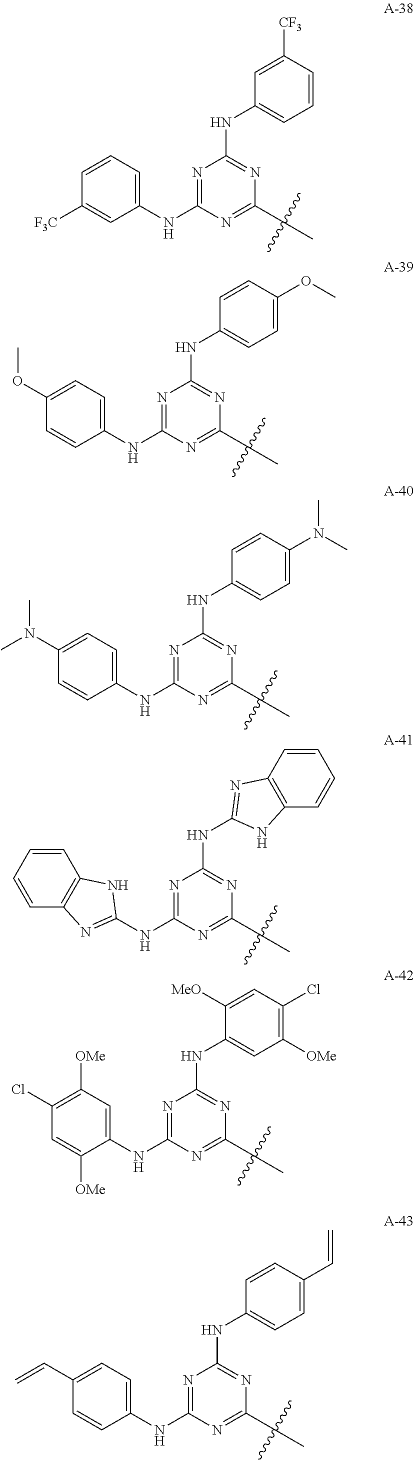

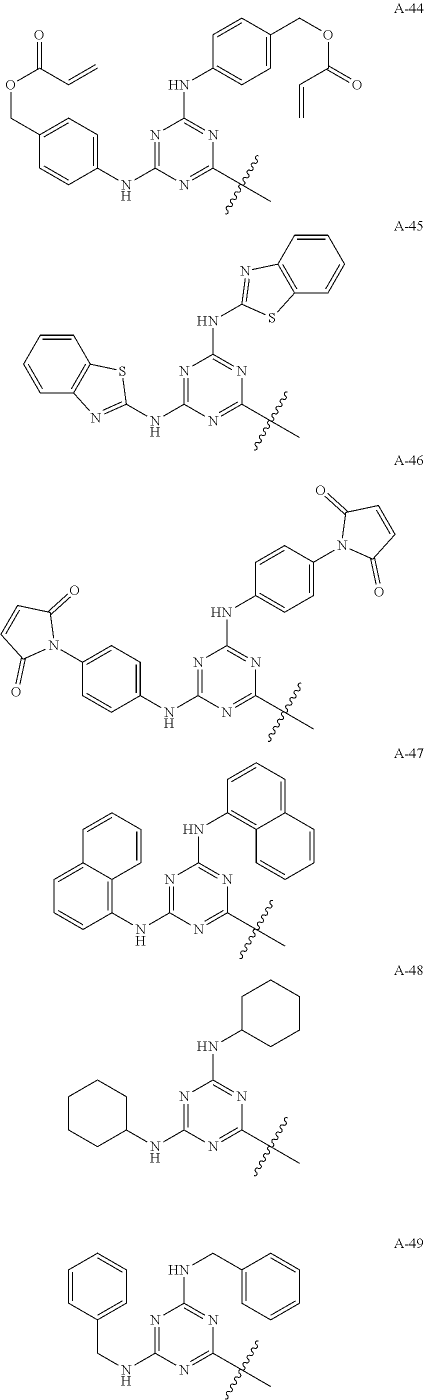 [SMILES: *c1nc(Nc2ccc(COC(=O)C=C)cc2)nc(Nc2ccc(COC(=O)C=C)cc2)n1 ; *c1nc(Nc2nc3ccccc3s2)nc(Nc2nc3ccccc3s2)n1 ; *c1nc(Nc2ccc(N3C(=O)C=CC3=O)cc2)nc(Nc2ccc(N3C(=O)C=CC3=O)cc2)n1 ; *c1nc(Nc2cccc3ccccc23)nc(Nc2cccc3ccccc23)n1 ; *c1nc(NC2CCCCC2)nc(NC2CCCCC2)n1 ; *c1nc(NCc2ccccc2)nc(NCc2ccccc2)n1]

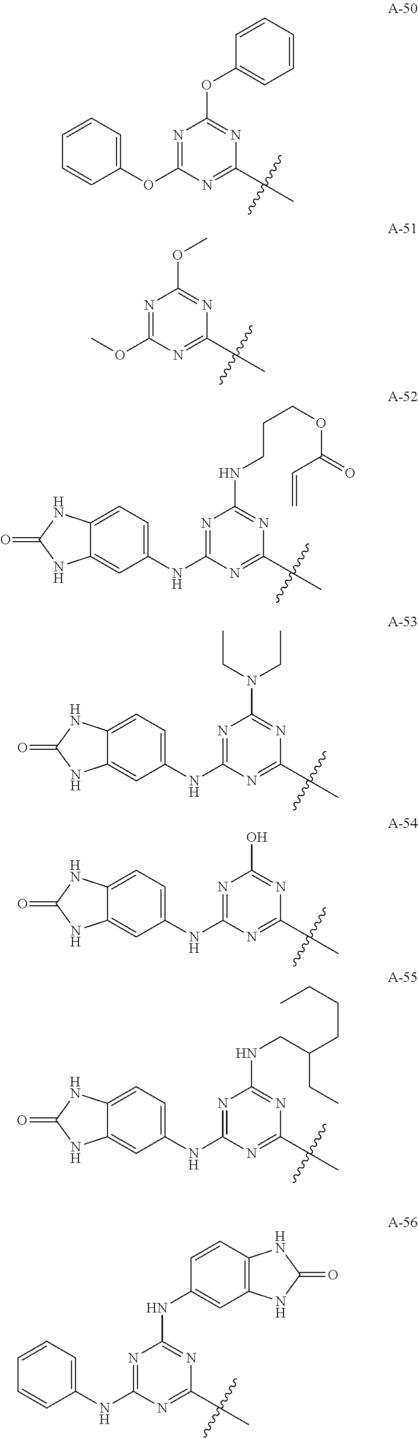

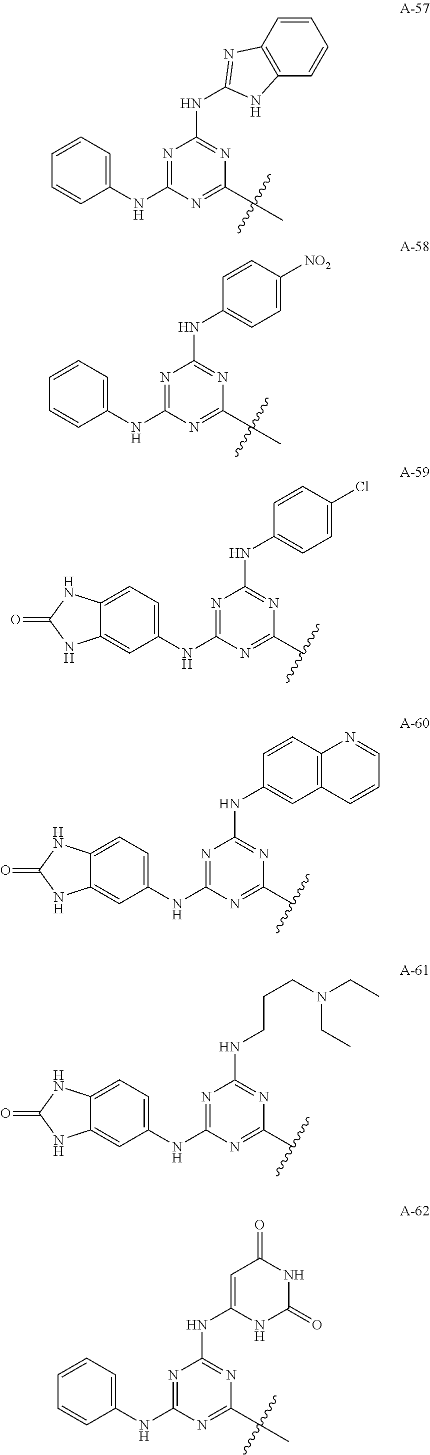 [SMILES: *c1nc(Nc2ccccc2)nc(Nc2nc3ccccc3[nH]2)n1 ; *c1nc(Nc2ccccc2)nc(Nc2ccc([N+](=O)[O-])cc2)n1 ; *c1nc(Nc2ccc(Cl)cc2)nc(Nc2ccc3[nH]c(=O)[nH]c3c2)n1 ; *c1nc(Nc2ccc3ncccc3c2)nc(Nc2ccc3[nH]c(=O)[nH]c3c2)n1 ; *c1nc(NCCCN(CC)CC)nc(Nc2ccc3[nH]c(=O)[nH]c3c2)n1 ; *c1nc(Nc2ccccc2)nc(Nc2cc(=O)[nH]c(=O)[nH]2)n1]

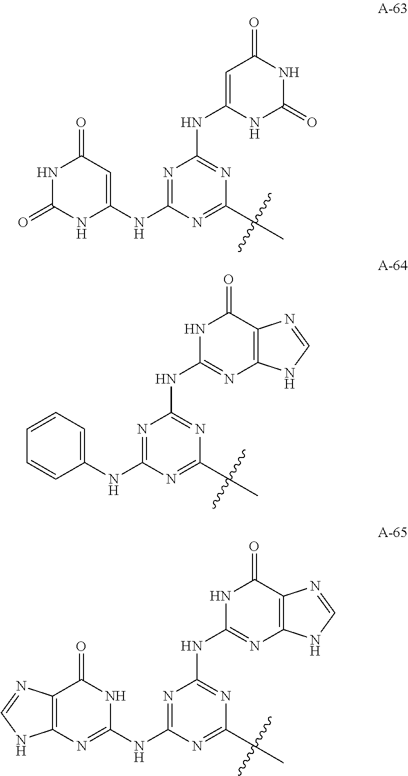 [SMILES: *c1nc(Nc2cc(=O)[nH]c(=O)[nH]2)nc(Nc2cc(=O)[nH]c(=O)[nH]2)n1 ; *c1nc(Nc2ccccc2)nc(Nc2nc3[nH]cnc3c(=O)[nH]2)n1 ; *c1nc(Nc2nc3[nH]cnc3c(=O)[nH]2)nc(Nc2nc3[nH]cnc3c(=O)[nH]2)n1]

The pigment derivative B1 preferably includes at least one group selected from an acid group or a basic group. The acid group is preferably at least one selected from a carboxyl group, a sulfo group, a phosphoric acid group, or a salt thereof, and more preferably at least one selected from a carboxyl group, a sulfo group, or a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. The basic group is preferably at least one selected from an amino group, a pyridyl group, salts thereof, a salt of an ammonium group, or a phthalimidomethyl group, more preferably at least one selected from an amino group, a salt of an amino group, or a salt of an ammonium group, and more preferably an amino group or a salt of an amino group. Examples of the amino group include —NH₂, a dialkylamino group, an alkylarylamino group, a diarylamino group, and a cyclic amino group. The dialkylamino group, alkylarylamino group, diarylamino group, and cyclic amino group may further have a substituent. Examples of the substituent include the above-described substituent T. Examples of an atom or atomic group constituting the salts include a hydroxide ion, a halogen ion, a carboxylate ion, a sulfonate ion, and a phenoxide ion.

The pigment derivative B1 is preferably a compound represented by Formula (b1).

A¹-I¹-Z¹ (b1)

In Formula (b1), A¹ represents a group including an aromatic ring,
L¹ represents a single bond or a divalent linking group, and
Z¹ represents a group having an acid group or a basic group.

A¹ in Formula (b1) represents a group including an aromatic ring. The aromatic ring included in A¹ may be an aromatic hydrocarbon ring or an aromatic heterocyclic ring. In addition, the aromatic ring may be a single ring or a fused ring.

Examples of the group represented by A¹ include a group including an aromatic ring selected from a benzene ring, a naphthalene ring, a fluorene ring, a perylene ring, an imidazole ring, a pyrazole ring, an oxazole ring, a thiazole ring, an imidazoline ring, a pyridine ring, a triazole ring, an imidazoline ring, a pyrazine ring, a pyrimidine ring, a pyridazine ring, a quinoline ring, an isoquinoline ring, a quinoxaline ring, a quinazoline ring, a benzimidazole ring, a benzopyrazole ring, a benzoxazole ring, a benzothiazole ring, a benzotriazole ring, an indole ring, an isoindole ring, a triazine ring, a pyrrole ring, a carbazole ring, a benzimidazolinone ring, a phthalimide ring, a phthalocyanine ring, an anthraquinone ring, a diketopyrrolopyrrole ring, an isoindolinone ring, an isoindoline ring, and a quinacridone ring; and a group including a fused ring including these aromatic rings. The above-described fused ring may be an aromatic ring or a non-aromatic ring, but is preferably an aromatic ring.

The group represented by A¹ may further have a substituent. Examples of the substituent include the above-described substituent T.

The group represented by A¹ is preferably a group including a benzimidazolinone ring or the group represented by Formula (A1), and more preferably the group represented by Formula (A1). In a case where Z¹ is a group represented by Formula (Z1) described later, it is particularly preferable that the group represented by A1 is the group represented by Formula (A1).

L¹ in Formula (b1) represents a single bond or a divalent linking group, and is preferably a divalent linking group. Examples of the divalent linking group represented by L¹ include an alkylene group, an arylene group, a heterocyclic group, —O—, —N(R^{L1})—, —NHCO—, —CONH—, —OCO—, —COO—, —CO—, —SO₂NH—, —SO₂—, and a group formed by a combination of these groups. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be any of linear, branched, and cyclic forms, and is preferably linear or branched and particularly preferably linear. The arylene group preferably has 6 to 30 carbon atoms and more preferably has 6 to 15 carbon atoms. The arylene group is preferably a phenylene group. R^{L1} represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by R^{L1} are the same as the ranges described as the preferred ranges of the alkyl group, alkenyl group, alkynyl group, and aryl group of Ra¹.

The divalent linking group represented by L¹ is preferably a group represented by Formula (L1).

-L^{1A}-L^{1B}-L^{1C}- (L1)

In the formula, L^{1A} and L^{1C} each independently represent —O—, —N(R^{L1})—, —NHCO—, —CONH—, —OCO—, —COO—, —CO—, —SO₂NH—, or —SO₂—, and L^{1B} represents a single bond or a divalent linking group.

Examples of the divalent linking group represented by L^{1B} include an alkylene group, an arylene group, a group in which an alkylene group and an arylene group are bonded to each other through a single bond, —O—, —N(R^{L1})—, —NHCO—, —CONH—, —OCO—, —COO—, —CO—, —SO₂NH—, —SO₂—, or a group formed by a combination of these groups, and a group in which alkylene groups or arylene groups are bonded to each other through —O—, —N(R^{L1})—, —NHCO—, —CONH—, —OCO—, —COO—, —CO—, —SO₂NH—, —SO₂—, or a group formed by a combination of these groups.

Specific examples of L¹ include groups having the following structures.

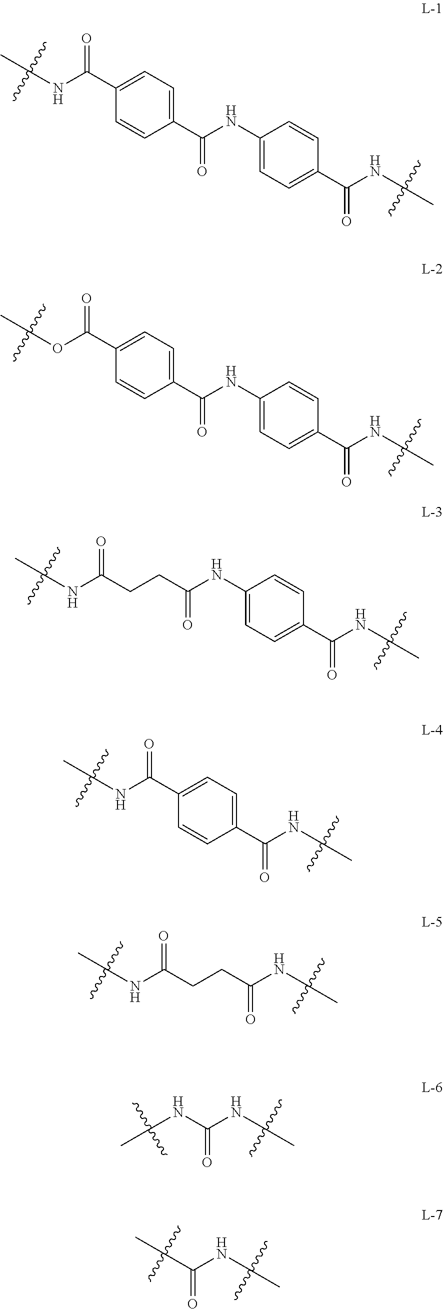

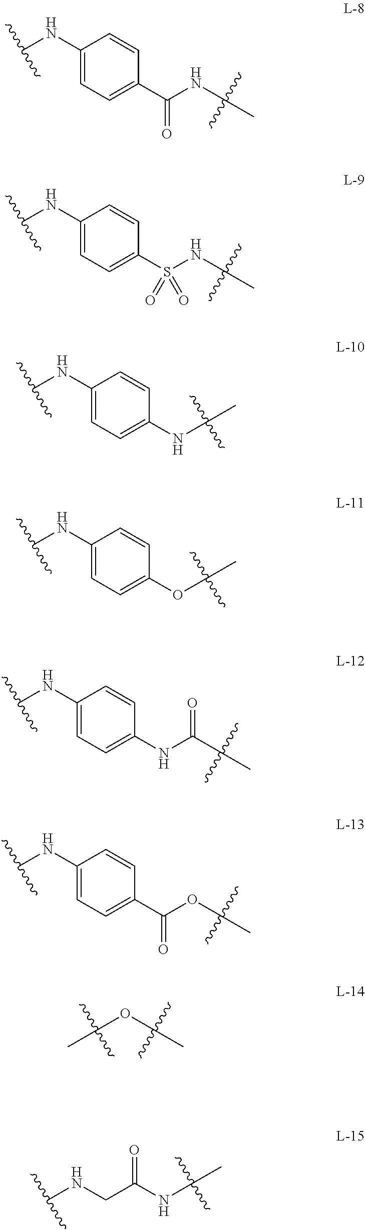

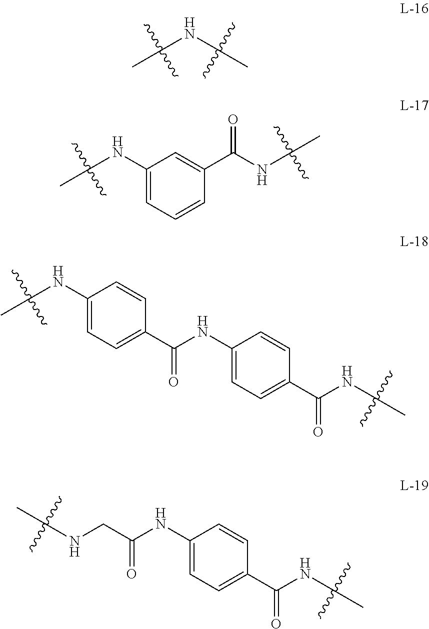

Z¹ in Formula (b1) represents a group having an acid group or a basic group. Examples of the types of the acid group and the basic group include the above-described groups.

Z¹ in Formula (b1) is preferably a group represented by Formula (Z1) or a group represented by Formula (Z10).

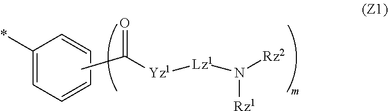

In Formula (Z1), * represents a bonding site,
Yz¹ represents —N(Ry¹)- or —O—, in which Ry¹ represents a hydrogen atom, an alkyl group, an alkenyl group, an alkynyl group, or an aryl group,
Lz¹ represents a divalent linking group,
Rz¹ and Rz² each independently represent a hydrogen atom, an alkyl group, an alkenyl group, an alkynyl group, or an aryl group, in which Rz¹ and Rz² may be bonded to each other through a divalent group to form a ring, and m represents an integer of 1 to 5.

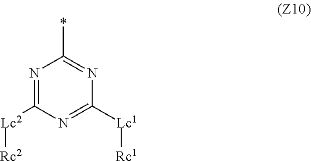

In Formula (Z10), * represents a bonding site, Lc¹ and Lc² each independently represent a single bond or a linking group, Rc¹ and Rc² each independently represent a substituent, and at least one of Rc¹ or Rc² represents an acid group or a basic group.

First, Formula (Z1) will be described.

In Formula (Z1), Yz¹ represents —N(Ry¹)- or —O—, and —N(Ry¹)- is preferable. Ry¹ represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by Ry¹ are the same as the ranges described as the preferred ranges of the alkyl group, alkenyl group, alkynyl group, and aryl group of Ra¹.

In Formula (Z1), examples of the divalent linking group represented by Lz¹ include an alkylene group, an arylene group, a heterocyclic group, —O—, —N(R^{L1})—, —NHCO—, —CONH—, —OCO—, —COO—, —CO—, —SO₂NH—, —SO₂—, and a group formed by a combination of these groups, and an alkylene group is preferable. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be any of linear, branched, and cyclic forms, and is preferably linear or branched and particularly preferably linear.

In Formula (Z1), Rz¹ and Rz² each independently represent a hydrogen atom, an alkyl group, an alkenyl group, an alkynyl group, or an aryl group, and an alkyl group or an aryl group is preferable and an alkyl group is more preferable. The alkyl group preferably has 1 to 10 carbon atoms, more preferably has 1 to 5 carbon atoms, still more preferably has 1 to 3 carbon atoms, and particularly preferably has 1 or 2 carbon atoms. The alkyl group may be any of linear, branched, and cyclic forms, and is preferably linear or branched and more preferably linear. The alkenyl group preferably has 2 to 10 carbon atoms, more preferably has 2 to 8 carbon atoms, and particularly preferably has 2 to 5 carbon atoms. The alkenyl group may be any of linear, branched, and cyclic forms, and is preferably linear or branched and more preferably linear. The alkynyl group preferably has 2 to 10 carbon atoms, more preferably has 2 to 8 carbon atoms, and particularly preferably has 2 to 5 carbon atoms. The alkynyl group may be any of linear, branched, and cyclic forms, and is preferably linear or branched and more preferably linear. The aryl group preferably has 6 to 30 carbon atoms, more preferably has 6 to 20 carbon atoms, and still more preferably has 6 to 12 carbon atoms.

In Formula (Z1), Rz¹ and Rz² may be bonded to each other through a divalent group to form a ring. Examples of the divalent group include —CH₂—, —O—, and —SO₂—. Specific examples of the ring formed by bonding Rz¹ and Rz² to each other through the divalent group include the following.

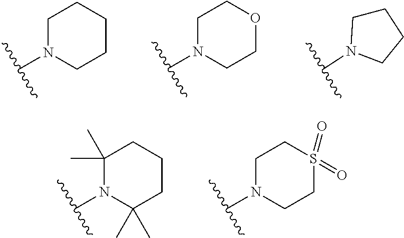

In Formula (Z1), m represents an integer of 1 to 5, and is preferably 1 to 4, more preferably 1 to 3, still more preferably 2 or 3, and particularly preferably 2.

The group represented by Formula (Z1) is preferably a group represented by Formula (Z2).

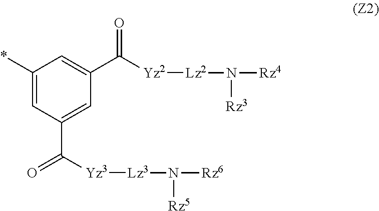

In Formula (Z2), * represents a bonding site,
Yz² and Yz³ each independently represent —N(Ry²)- or —O—, in which Ry² represents a hydrogen atom, an alkyl group, an alkenyl group, an alkynyl group, or an aryl group,
Lz² and Lz³ each independently represent a divalent linking group, and
Rz³ to Rz⁶ each independently represent a hydrogen atom, an alkyl group, an alkenyl group, an alkynyl group, or an aryl group, and
Rz³ and Rz⁴, and Rz⁵ and Rz⁶ may be respectively bonded to each other through a divalent group to form a ring.

Yz² and Yz³ in Formula (Z2) have the same meanings as Yz¹ in Formula (Z1), and the preferred ranges are also the same. Ry² represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by Ry² are the same as the ranges described as the preferred ranges of the alkyl group, alkenyl group, alkynyl group, and aryl group of Ra¹.

Lz² and Lz³ in Formula (Z2) have the same meanings as Lz¹ in Formula (Z1), and the preferred ranges are also the same. Rz³ to Rz⁶ in Formula (Z2) have the same meanings as Rz¹ and Rz² in Formula (Z1), and the preferred ranges are also the same.

Next, Formula (Z10) will be described.

In Formula (Z10), Lc¹ and Lc² each independently represent a single bond or a linking group, and a divalent linking group is preferable. Examples of the divalent linking group include an alkylene group, an arylene group, —O—, —N(R^{L1})—, —NHCO—, —CONH—, —OCO—, —COO—, —CO—, —SO₂NH—, —SO₂—, and a group formed by a combination of these groups. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be any of linear, branched, and cyclic forms, and is preferably linear or branched and particularly preferably linear. The arylene group preferably has 6 to 30 carbon atoms and more preferably has 6 to 15 carbon atoms. The arylene group is preferably a phenylene group. R^{L1} represents a hydrogen atom, an alkyl group, or an aryl group, and a hydrogen atom or an alkyl group is preferable and a hydrogen atom is more preferable. The alkyl group represented by R^{L1} preferably has 1 to 20 carbon atoms, more preferably has 1 to 15 carbon atoms, and still more preferably has 1 to 8 carbon atoms. The alkyl group may be any of linear, branched, and cyclic forms, and is preferably linear or branched and more preferably linear. The alkyl group represented by R^{L1} may further have a substituent. Examples of the substituent include the above-described substituent T. The aryl group represented by R^{L1} preferably has 6 to 30 carbon atoms, more preferably has 6 to 20 carbon atoms, and still more preferably has 6 to 12 carbon atoms. The aryl group represented by R^{L1} may further have a substituent. Examples of the substituent include the above-described substituent T.

In Formula (Z10), Rc¹ and Rc² each independently represent a substituent. Examples of the substituent include an alkyl group, an aryl group, a heterocyclic group, a hydroxyl group, an acid group, and a basic group. However, at least one of Rc¹ or Rc² represents an acid group or a basic group. It is preferable that at least one of Rc¹ or Rc² is a basic group, and it is more preferable that both Rc¹ and Rc² are basic groups. Examples of the acid group and the basic group include those described above. The alkyl group preferably has 1 to 30 carbon atoms, more preferably has 1 to 15 carbon atoms, and still more preferably has 1 to 8 carbon atoms. The alkyl group may be any of linear, branched, and cyclic forms, and is preferably linear or branched and more preferably linear. The aryl group preferably has 6 to 30 carbon atoms, more preferably has 6 to 20 carbon atoms, and still more preferably has 6 to 12 carbon atoms. The heterocyclic group may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12. The alkyl group, aryl group, and heterocyclic group may further have a substituent. Examples of the substituent include the above-described substituent T.

The group represented by Formula (Z10) is preferably a group represented by Formula (Z11), and more preferably a group represented by Formula (Z12).

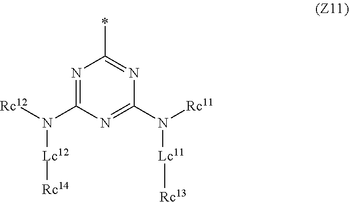

In Formula (Z11), * represents a bonding site, Lc¹¹ and Lc¹² each independently represent a single bond or a linking group, Rc¹¹ and Rc¹² each independently represent a hydrogen atom or a substituent, Rc¹³ and Rc¹⁴ each independently represent a substituent, and at least one of Rc¹³ or Rc¹⁴ represents an acid group or a basic group.

Rc¹³ and Rc¹⁴ in Formula (Z11) have the same meaning as R^{c} and Rc² in Formula (Z10), and the preferred ranges are also the same.

In Formula (Z11), Rc¹¹ and Rc¹² each independently represent a hydrogen atom or a substituent. Examples of the substituent represented by Rc¹¹ and Rc¹² include an alkyl group and an aryl group. The alkyl group preferably has 1 to 20 carbon atoms, more preferably has 1 to 15 carbon atoms, and still more preferably has 1 to 8 carbon atoms. The alkyl group may be any of linear, branched, and cyclic forms, and is preferably linear or branched and more preferably linear. The aryl group preferably has 6 to 30 carbon atoms, more preferably has 6 to 20 carbon atoms, and still more preferably has 6 to 12 carbon atoms. The alkyl group and aryl group may further have a substituent. Examples of the substituent include the above-described substituent T. Rc¹¹ and Rc¹² are preferably hydrogen atoms.

In Formula (Z11), Lc¹¹ and Lc¹² each independently represent a single bond or a linking group, and a divalent linking group is preferable. Examples of the divalent linking group include an alkylene group, an arylene group, —O—, —N(R^{L11})—, —NHCO—, —CONH—, —OCO—, —COO—, —CO—, —SO₂NH—, —SO₂—, and a group formed by a combination of these groups, and a group including at least one selected from an alkylene group or an arylene group is preferable, a group including an alkylene group is more preferable, and an alkylene group is still more preferable. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be any of linear, branched, and cyclic forms, and is preferably linear or branched and particularly preferably linear. The arylene group preferably has 6 to 30 carbon atoms and more preferably has 6 to 15 carbon atoms. The arylene group is preferably a phenylene group. R^{L1} represents a hydrogen atom, an alkyl group, or an aryl group, and a hydrogen atom or an alkyl group is preferable and a hydrogen atom is more preferable. The alkyl group and aryl group represented by R^{L11} have the same meaning as the alkyl group and aryl group represented by R^{L1} described above.

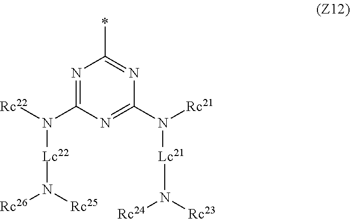

In Formula (Z12), * represents a bonding site, Lc²¹ and Lc²² each independently represent a single bond or a linking group, Rc²¹ and Rc²² each independently represent a hydrogen atom or a substituent, Rc²³ to Rc²⁶ each independently represent a hydrogen atom or a substituent, Rc²³ and Rc²⁴ may be bonded to each other through a divalent group to form a ring, and Rc²⁵ and Rc²⁶ may be bonded to each other through a divalent group to form a ring. Rc²¹ and Rc²² in Formula (Z12) have the same meaning as Rc¹¹ and Rc¹² in Formula (Z11), and the preferred ranges are also the same. Lc²¹ and Lc²² in Formula (Z12) have the same meaning as Lc¹¹ and Lc¹² in Formula (Z11), and the preferred ranges are also the same.

In Formula (Z12), Rc²³ to Rc²⁶ each independently represent a hydrogen atom or a substituent, and a substituent is preferable. Examples of the substituent include an alkyl group and an aryl group, and an alkyl group is preferable. The alkyl group preferably has 1 to 10 carbon atoms, more preferably has 1 to 5 carbon atoms, and still more preferably has 1 to 3 carbon atoms. The alkyl group may be any of linear, branched, and cyclic forms, and is preferably linear or branched and more preferably linear. The aryl group preferably has 6 to 30 carbon atoms, more preferably has 6 to 20 carbon atoms, and still more preferably has 6 to 12 carbon atoms. The alkyl group and aryl group may further have a substituent. Examples of the substituent include the above-described substituent T.

In Formula (Z12), Rc²³ and Rc²⁴ may be bonded to each other through a divalent group to form a ring, and Rc²⁵ and Rc²⁶ may be bonded to each other through a divalent group to form a ring. Examples of the divalent group include —CH₂—, —O—, and —SO₂—. Specific examples of the ring formed by bonding the above-described groups to each other through the divalent group include the following.

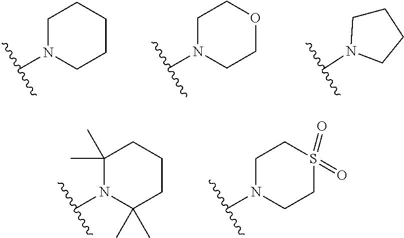 [SMILES: *N1CCCCC1 ; *N1CCOCC1 ; *N1CCCC1 ; *N1C(C)(C)CCCC1(C)C ; *N1CCS(=O)(=O)CC1]

Specific examples of Z¹ include groups having the following structures. In the following structural formulae, Ph represents a phenyl group.

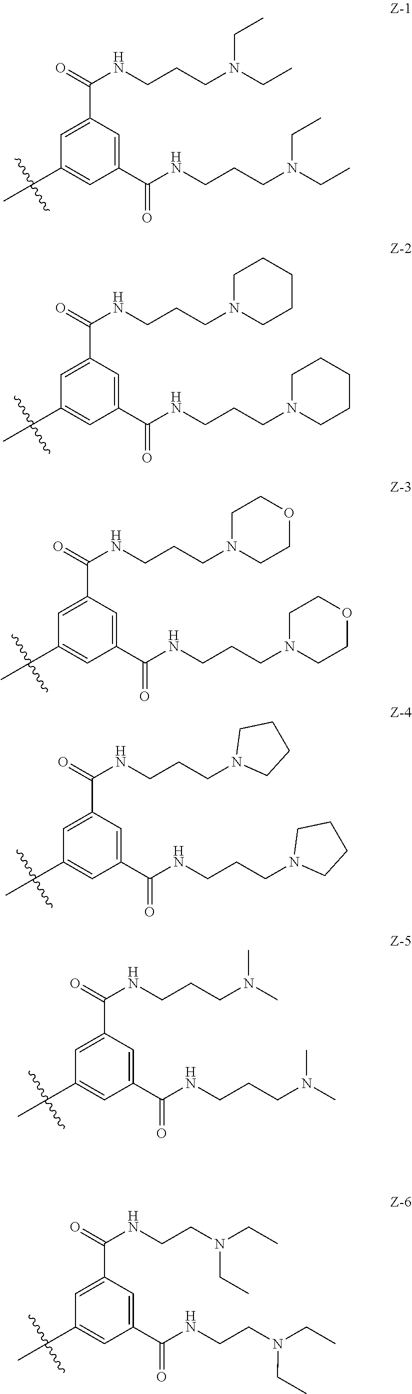 [SMILES: *c1cc(C(=O)NCCCN(CC)CC)cc(C(=O)NCCCN(CC)CC)c1 ; *c1cc(C(=O)NCCCN2CCCCC2)cc(C(=O)NCCCN2CCCCC2)c1 ; *c1cc(C(=O)NCCCN2CCOCC2)cc(C(=O)NCCCN2CCOCC2)c1 ; *c1cc(C(=O)NCCCN2CCCC2)cc(C(=O)NCCCN2CCCC2)c1 ; *c1cc(C(=O)NCCCN(C)C)cc(C(=O)NCCCN(C)C)c1 ; *c1cc(C(=O)NCCN(CC)CC)cc(C(=O)NCCN(CC)CC)c1]

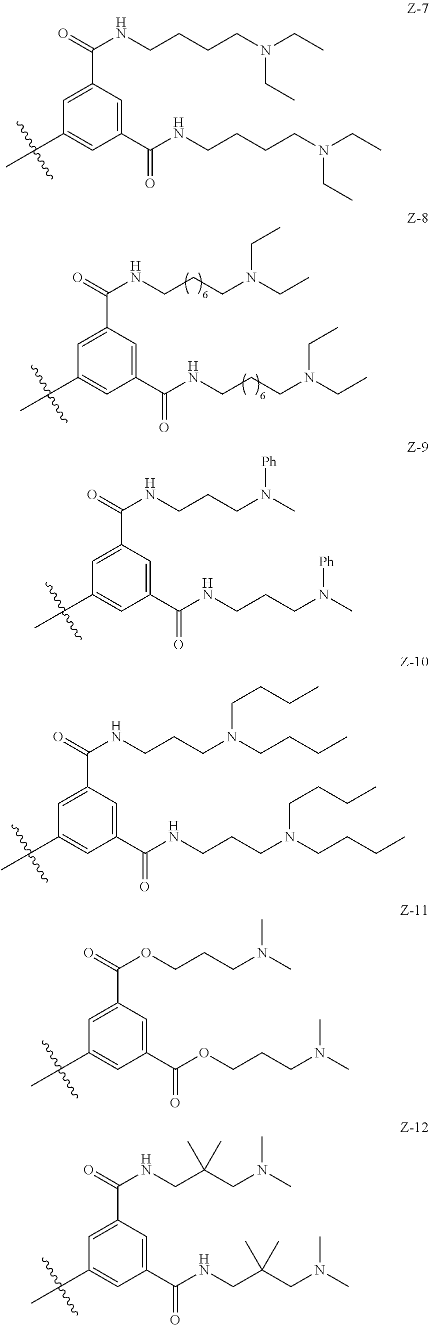

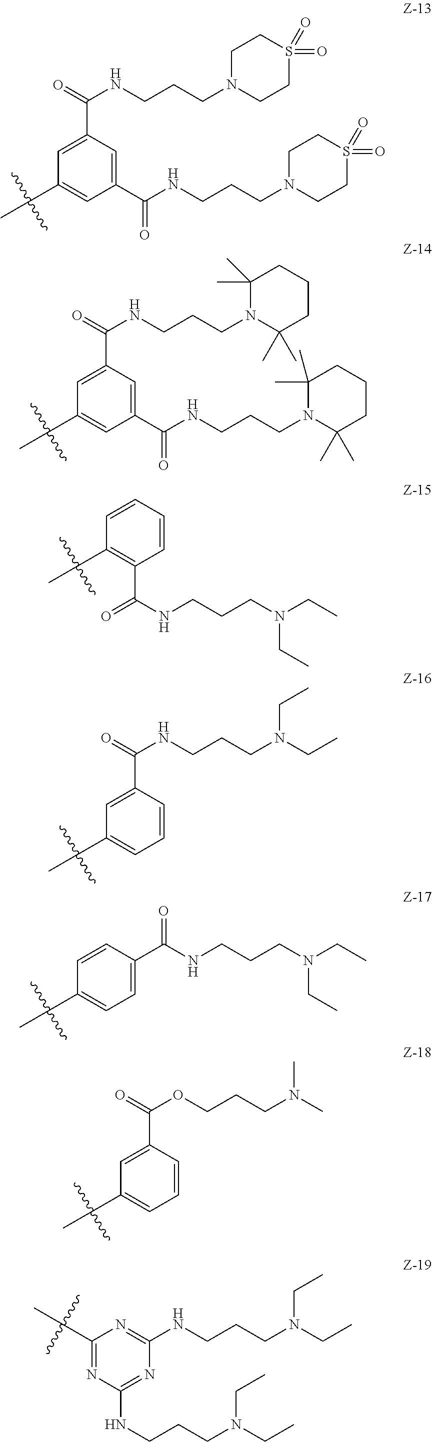

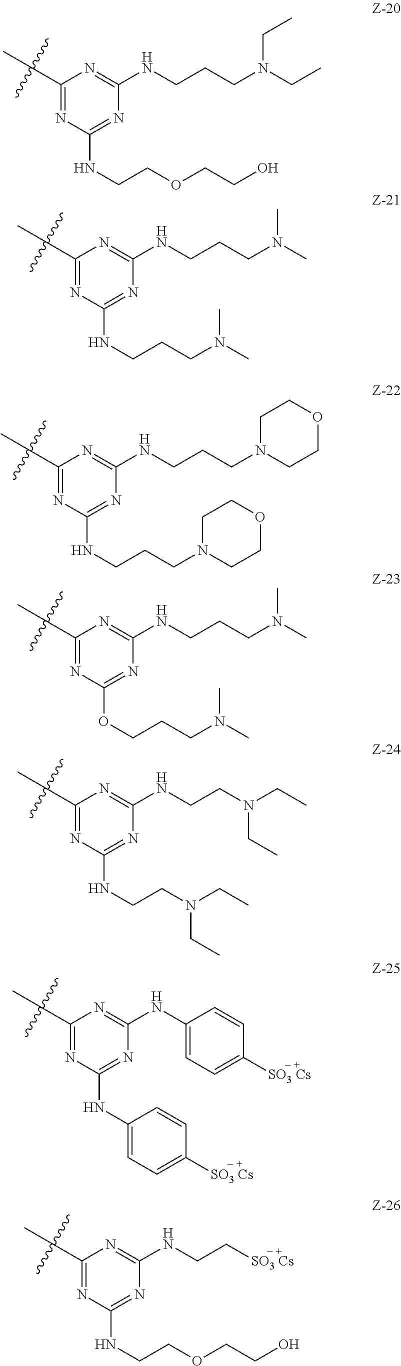

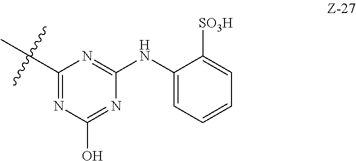 [SMILES: *c1nc(O)nc(Nc2ccccc2S(=O)(=O)O)n1]

The pigment derivative B1 is preferably a compound represented by Formula (b2). By using such a compound, the effects of the present invention are more remarkably obtained.

A¹-X¹-L²-X²—Z¹ (b2)

In Formula (b2), A¹ represents a group including an aromatic ring,
X¹ and X² each independently represent a single bond, —O—, —N(R¹)—, —NHCO—, —CONH—, —OCO—, —COO—, —CO—, —SO₂NH—, or —SO₂—, where R¹ represents a hydrogen atom, an alkyl group, an alkenyl group, an alkynyl group, or an aryl group,
L² represents a single bond or a divalent linking group, and
Z¹ represents the group represented by Formula (Z1).

A¹ and Z¹ in Formula (b2) have the same meanings as A¹ and Z¹ in Formula (b1), and the preferred ranges are also the same.

X¹ and X² in Formula (b2) each independently represent a single bond, —O—, —N(R¹)—, —NHCO—, —CONH—, —OCO—, —COO—, —CO—, —SO₂NH—, or —SO₂—, —O—, —N(R¹)—, —NHCO—, —CONH—, —OCO—, —COO—, —CO—, —SO₂NH—, or —SO₂— is preferable. R¹ represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by R¹ are the same as the ranges described as the preferred ranges of the alkyl group, alkenyl group, alkynyl group, and aryl group of Ra¹.

L² in Formula (b2) represents a single bond or a divalent linking group. Examples of the divalent linking group represented by L² include an alkylene group, an arylene group, a group in which an alkylene group and an arylene group are bonded to each other through a single bond, —O—, —N(R²)—, —NHCO—, —CONH—, —OCO—, —COO—, —CO—, —SO₂NH—, —SO₂—, or a group formed by a combination of these groups, and a group in which alkylene groups or arylene groups are bonded to each other through —O—, —N(R²)—, —NHCO—, —CONH—, —OCO—, —COO—, —CO—, —SO₂NH—, —SO₂—, or a group formed by a combination of these groups. R² represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by R² are the same as the ranges described as the preferred ranges of the alkyl group, alkenyl group, alkynyl group, and aryl group of Ra¹.

Specific examples of the pigment derivative B1 include compounds shown below and compounds described in Examples described later. In the following table, the symbols described in the columns of structure of A¹, structure of L¹, and structure of Z¹ are the structures exemplified in the specific examples of A¹ (that is, specific examples of the group represented by Formula (A1)), the specific examples of L¹, and the specific examples of Z¹ respectively.

TABLE 1
A¹-L¹-Z¹

| Compound | Structure | Structure | Structure |
|---|---|---|---|
| No. | of A¹ | of L¹ | of Z¹ |
| C-1 | A-1 | L-1 | Z-1 |
| C-2 | A-2 | L-1 | Z-1 |
| C-3 | A-3 | L-1 | Z-1 |
| C-4 | A-4 | L-1 | Z-1 |
| C-5 | A-5 | L-1 | Z-1 |
| C-6 | A-6 | L-1 | Z-1 |
| C-7 | A-7 | L-1 | Z-1 |
| C-8 | A-8 | L-1 | Z-1 |
| C-9 | A-9 | L-1 | Z-1 |
| C-10 | A-10 | L-1 | Z-1 |
| C-11 | A-11 | L-1 | Z-1 |
| C-12 | A-12 | L-1 | Z-1 |
| C-13 | A-13 | L-1 | Z-1 |
| C-14 | A-14 | L-1 | Z-1 |
| C-15 | A-15 | L-1 | Z-1 |
| C-16 | A-16 | L-1 | Z-1 |
| C-17 | A-17 | L-1 | Z-1 |
| C-18 | A-18 | L-1 | Z-1 |
| C-19 | A-19 | L-1 | Z-1 |
| C-20 | A-20 | L-1 | Z-1 |
| C-21 | A-21 | L-1 | Z-1 |
| C-22 | A-22 | L-1 | Z-1 |
| C-23 | A-23 | L-1 | Z-1 |
| C-24 | A-24 | L-1 | Z-1 |
| C-25 | A-25 | L-2 | Z-1 |
| C-26 | A-26 | L-2 | Z-1 |
| C-27 | A-16 | L-3 | Z-1 |
| C-28 | A-16 | L-4 | Z-1 |
| C-29 | A-16 | L-5 | Z-1 |
| C-30 | A-16 | L-6 | Z-1 |
| C-31 | A-7 | L-7 | Z-1 |
| C-32 | A-28 | L-7 | Z-1 |
| C-33 | A-29 | L-8 | Z-1 |
| C-34 | A-30 | L-8 | Z-1 |
| C-35 | A-31 | L-8 | Z-1 |
| C-36 | A-32 | L-8 | Z-1 |
| C-37 | A-33 | L-8 | Z-1 |
| C-38 | A-34 | L-8 | Z-1 |
| C-39 | A-35 | L-8 | Z-1 |
| C-40 | A-36 | L-8 | Z-1 |
| C-41 | A-37 | L-8 | Z-1 |
| C-42 | A-38 | L-8 | Z-1 |
| C-43 | A-39 | L-8 | Z-1 |
| C-44 | A-40 | L-8 | Z-1 |
| C-45 | A-41 | L-8 | Z-1 |
| C-46 | A-42 | L-8 | Z-1 |
| C-47 | A-43 | L-8 | Z-1 |
| C-48 | A-44 | L-8 | Z-1 |
| C-49 | A-45 | L-8 | Z-1 |
| C-50 | A-46 | L-8 | Z-1 |
| C-51 | A-47 | L-8 | Z-1 |
| C-52 | A-48 | L-8 | Z-1 |
| C-53 | A-49 | L-8 | Z-1 |
| C-54 | A-50 | L-8 | Z-1 |
| C-55 | A-51 | L-8 | Z-1 |
| C-56 | A-52 | L-8 | Z-1 |
| C-57 | A-53 | L-8 | Z-1 |
| C-58 | A-54 | L-8 | Z-1 |
| C-59 | A-55 | L-8 | Z-1 |
| C-60 | A-56 | L-8 | Z-1 |
| C-61 | A-57 | L-8 | Z-1 |
| C-62 | A-58 | L-8 | Z-1 |
| C-63 | A-32 | L-9 | Z-1 |
| C-64 | A-32 | L-10 | Z-1 |
| C-65 | A-32 | L-11 | Z-1 |
| C-66 | A-32 | L-12 | Z-1 |
| C-67 | A-32 | L-13 | Z-1 |
| C-68 | A-32 | L-14 | Z-1 |
| C-69 | A-32 | L-15 | Z-1 |
| C-70 | A-32 | L-16 | Z-1 |
| C-71 | A-32 | L-17 | Z-1 |
| C-72 | A-32 | L-18 | Z-1 |
| C-73 | A-32 | L-19 | Z-1 |
| C-74 | A-32 | L-8 | Z-2 |
| C-75 | A-32 | L-8 | Z-3 |
| C-76 | A-32 | L-8 | Z-4 |
| C-77 | A-32 | L-8 | Z-5 |
| C-78 | A-32 | L-8 | Z-6 |
| C-79 | A-32 | L-8 | Z-7 |
| C-80 | A-32 | L-8 | Z-8 |
| C-81 | A-32 | L-8 | Z-9 |
| C-82 | A-32 | L-8 | Z-10 |
| C-83 | A-32 | L-8 | Z-11 |
| C-84 | A-32 | L-8 | Z-12 |
| C-85 | A-32 | L-8 | Z-13 |
| C-86 | A-32 | L-8 | Z-14 |
| C-87 | A-32 | L-8 | Z-15 |
| C-88 | A-32 | L-8 | Z-16 |
| C-89 | A-32 | L-8 | Z-17 |
| C-90 | A-32 | L-8 | Z-18 |
| C-91 | A-16 | L-1 | Z-17 |
| C-92 | A-15 | L-1 | Z-17 |
| C-93 | A-59 | L-8 | Z-1 |
| C-94 | A-60 | L-8 | Z-1 |
| C-95 | A-61 | L-8 | Z-1 |
| C-96 | A-62 | L-8 | Z-1 |
| C-97 | A-63 | L-8 | Z-1 |
| C-98 | A-64 | L-8 | Z-1 |
| C-99 | A-65 | L-8 | Z-1 |

### (Pigment Derivative B2)

Next, the pigment derivative B2 will be described. The pigment derivative B2 is a chromatic pigment derivative. Examples of the pigment derivative B2 include a compound having a structure in which a part of a chromophore is substituted with an acid group or a basic group.

The acid group is preferably at least one selected from a carboxyl group, a sulfo group, a phosphoric acid group, or a salt thereof, and more preferably at least one selected from a carboxyl group, a sulfo group, or a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. The basic group is preferably at least one selected from an amino group, a pyridyl group, salts thereof, a salt of an ammonium group, or a phthalimidomethyl group, more preferably at least one selected from an amino group, a salt of an amino group, or a salt of an ammonium group, and more preferably an amino group or a salt of an amino group. Examples of the amino group include —NH₂, a dialkylamino group, an alkylarylamino group, a diarylamino group, and a cyclic amino group. The dialkylamino group, alkylarylamino group, diarylamino group, and cyclic amino group may further have a substituent. Examples of the substituent include the above-described substituent T. Examples of an atom or atomic group constituting the salts include a hydroxide ion, a halogen ion, a carboxylate ion, a sulfonate ion, and a phenoxide ion.

Examples of the chromophore constituting the pigment derivative B2 include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, from the reason that it is easy to form a film having more excellent light resistance, a phthalocyanine skeleton, a benzimidazolone skeleton, or a dioxazine skeleton is preferable, and a phthalocyanine skeleton is more preferable. That is, the pigment derivative B2 is preferably a phthalocyanine compound, a benzimidazolone compound, or a dioxazine compound, and more preferably a phthalocyanine compound.

The maximal absorption wavelength of the pigment derivative B2 is preferably in a wavelength range of 400 to 700 nm. Examples of a hue exhibited by the pigment derivative B2 include blue, violet, red, yellow, and green, and from the reason that it is easy to form a film having more excellent light resistance, a phthalocyanine skeleton, the hue is preferably blue or violet.

The maximum value of a molar absorption coefficient of the pigment derivative B2 in a wavelength range of 400 to 700 nm is preferably 10,000 L·mol⁻¹·cm⁻¹ or more, more preferably 15,000 L·mol⁻¹·cm⁻¹ or more, and still more preferably 20,000 L·mol⁻¹·cm⁻¹ or more. The upper limit thereof is preferably 200,000 L·mol⁻¹·cm⁻¹ or less.

A difference between the maximum value of the molar absorption coefficient of the pigment derivative B2 in a wavelength range of 400 to 700 nm and the maximum value of the molar absorption coefficient of the pigment derivative B1 in a wavelength range of 400 to 700 nm is preferably 10,000 L·mol⁻¹·cm⁻¹ or more, more preferably 20,000 L·mol⁻¹·cm⁻¹ or more, and still more preferably 30,000 L·mol⁻¹·cm⁻¹ or more. The upper limit thereof is preferably 200,000 L·mol⁻¹·cm⁻¹ or less.

In a case where the pigment derivative B1 is a compound having an acid group, the pigment derivative B2 is preferably a compound having an acid group.

In addition, in a case where the pigment derivative B1 is a compound having a basic group, the pigment derivative B2 is preferably a compound having a basic group.

The content of the pigment derivative B in the total solid content of the photosensitive composition is preferably 0.5% to 40% by mass. The lower limit thereof is preferably 1% by mass or more and more preferably 2% by mass or more. The upper limit thereof is preferably 20% by mass or less and more preferably 15% by mass or less.

In addition, the content of the pigment derivative B is preferably 1 to 60 parts by mass with respect to 100 parts by mass of the total of the colorant A and the pigment derivative B. The lower limit thereof is preferably 2 parts by mass or more and more preferably 3 parts by mass or more. The upper limit is preferably 40 parts by mass or less and more preferably 30 parts by mass or less.

In addition, the content of the pigment derivative B2 is preferably 1 to 90 parts by mass with respect to 100 parts by mass of the total of the pigment derivative B1. The lower limit thereof is preferably 2 parts by mass or more and more preferably 5 parts by mass or more. The upper limit thereof is preferably 80 parts by mass or less and more preferably 70 parts by mass or less.

### <<Resin C>>

The photosensitive composition according to the embodiment of the present invention contains a resin C (hereinafter, referred to as a resin). The resin is blended in, for example, an application for dispersing the pigment in the photosensitive composition or an application as a binder. Mainly, a resin which is used for dispersing the pigment in the photosensitive composition is also referred to as a dispersant. The resin as a dispersant can be used in a case of preparing a dispersion liquid. However, such applications of the resin are merely exemplary, and the resin can also be used for other purposes in addition to such applications.

A weight-average molecular weight (Mw) of the resin is preferably 2,000 to 2,000,000. The upper limit is preferably 1000000 or less and more preferably 500000 or less. The lower limit is preferably 3000 or more, more preferably 4000 or more, and still more preferably 5000 or more.

Examples of the resin include a (meth)acrylic resin, a (meth)acrylamide resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, and a siloxane resin. In addition, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, resins described in JP2017-066240A, resins described in JP2020-122052A, resins described in JP2020-111656A, resins described in JP2020-139021A, alkali-soluble resins having an urea-functional group, described in JP2020-139021A, resins including a constitutional unit having a ring structure in the main chain and a constitutional unit having a biphenyl group in the side chain, described in JP2017-138503A, resins described in paragraphs 0199 to 0233 of JP2020-186373A, alkali-soluble resins described in JP2020-186325A, and resins represented by Formula 1, described in KR10-2020-0078339A, can be used. In addition, as the resin, a resin having a glass transition temperature of 390° C. or higher can also be used. Examples of a commercially available product of the resin having a glass transition temperature of 390° C. or higher include Polyimide varnish H520 manufactured by MITSUBISHI GAS CHEMICAL COMPANY, INC.

As the resin, it is preferable to use a resin having an acid group. Examples of the acid group include a carboxy group, a phosphoric acid group, a sulfo group, and a phenolic hydroxy group. Among these acid groups, one kind may be used alone, or two or more kinds may be used in combination. The resin having an acid group can be used, for example, as an alkali-soluble resin. An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 200 mgKOH/g or less, still more preferably 150 mgKOH/g or less, and most preferably 120 mgKOH/g or less.

The resin also preferably includes a resin including a repeating unit derived from a compound represented by Formula (ED1) and/or a compound represented by Formula (ED2) (hereinafter, these compounds will also be referred to as an “ether dimer”).

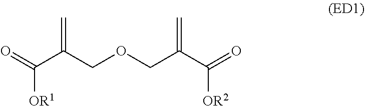

In Formula (ED1), R¹ and R² each independently represent a hydrogen atom or a hydrocarbon group having 1 to 25 carbon atoms, which may have a substituent.

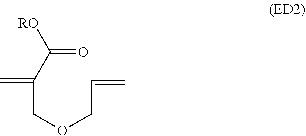

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

As the resin, a resin having a basic group can also be used. Examples of the resin having a basic group include a copolymer which has a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK-Chemie), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF). In addition, as the resin having a basic group, block copolymer (B) described in paragraph Nos. 0063 to 0112 of JP2014-219665A, block copolymer A1 described in paragraph Nos. 0046 to 0076 of JP2018-156021A, and a vinyl resin having a basic group, described in paragraph Nos. 0150 to 0153 of JP2019-184763A, can also be used, the contents of which are incorporated herein by reference.

As the resin, it is also preferable to use a resin having an ethylenically unsaturated bond-containing group. Examples of the ethylenically unsaturated bond-containing group include a vinyl group, a (meth)allyl group, and a (meth)acryloyl group. From the viewpoint of developability and curing properties, an ethylenically unsaturated bond-containing group value (hereinafter, also referred to as C═C value) of the resin is preferably 0.01 to 2.0 mmol/g, more preferably 0.1 to 1.5 mmol/g, and still more preferably 0.1 to 1.0 mmol/g. The C═C value of the resin is a numerical value indicating a molar amount of ethylenically unsaturated bond-containing groups per 1 g of the solid content of the resin. In a case where the C═C value of the resin can be calculated from raw materials used for the synthesis of the resin, a value calculated from the raw materials charged is used. In addition, for the C═C value of the resin, in a case where the value cannot be calculated from the raw materials used for the synthesis of the resin, a value measured by a hydrolysis method is used. Specifically, a low-molecular-weight component (a) of an ethylenically unsaturated bond-containing group site is extracted from the resin by an alkali treatment, a content of the low-molecular-weight component (a) is measured by high-performance liquid chromatography (HPLC), and the ethylenically unsaturated bond-containing group value of the resin can be calculated by the following expression. In addition, in a case where the above-described low-molecular-weight component (a) cannot be extracted from the resin by an alkali treatment, a value measured by a nuclear magnetic resonance (NMR) method is used.

C═C Value [mmol/g] of resin=(Content [ppm] of Low-molecular-weight component (a)/Molecular weight [g/mol] of low-molecular-weight component (a)/(Weighed value [g] of resin)×(Concentration of solid contents [% by mass] of Resin/100)×10)

As the resin, it is also preferable to use a resin including a repeating unit derived from a compound represented by Formula (X).

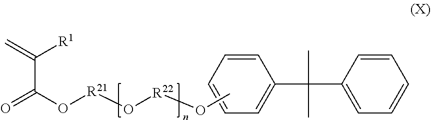

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to use a resin (hereinafter, also referred to as a resin Ac) having an aromatic carboxy group. The resin Ac may include the aromatic carboxy group in the main chain of the repeating unit, or in the side chain of the repeating unit. It is preferable that the aromatic carboxy group is included in the main chain of the repeating unit. In the present specification, the aromatic carboxy group is a group having a structure in which one or more carboxyl groups are bonded to an aromatic ring. In the aromatic carboxy group, the number of carboxyl groups bonded to an aromatic ring is preferably 1 to 4 and more preferably 1 or 2.

The resin Ac is preferably a resin including at least one repeating unit selected from a repeating unit represented by Formula (Ac-1) and a repeating unit represented by Formula (Ac-2).

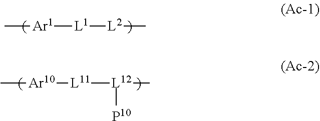

In Formula (Ac-1), Ar¹ represents a group including an aromatic carboxy group, L¹ represents —COO— or —CONH—, and L² represents a divalent linking group.

In Formula (Ac-2), Ar¹⁰ represents a group including an aromatic carboxy group, L¹¹ represents —COO— or —CONH—, L¹² represents a trivalent linking group, and P¹⁰ represents a polymer chain.

In Formula (Ac-1), examples of the group including an aromatic carboxy group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

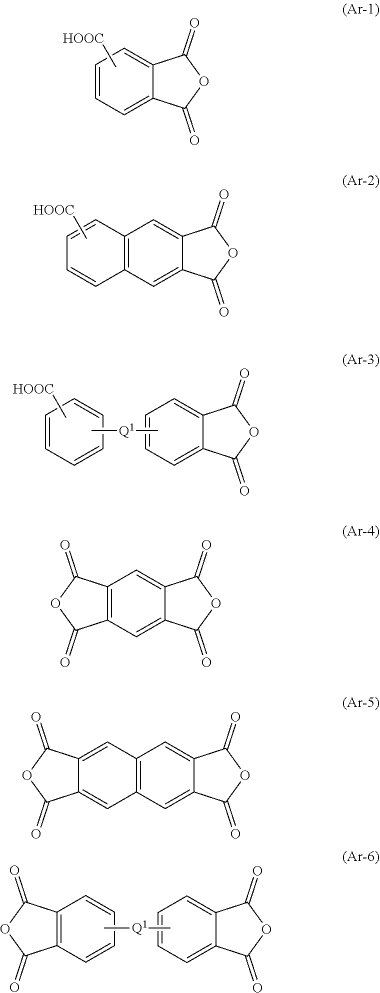

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

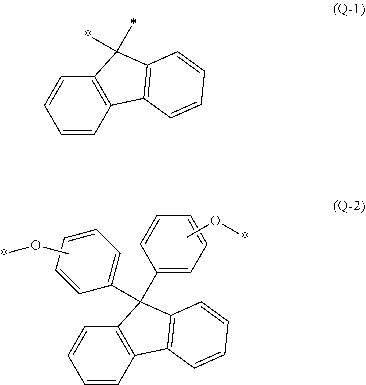

The group including an aromatic carboxyl group, represented by Art, may have a polymerizable group. As the polymerizable group, an ethylenically unsaturated bond-containing group or a cyclic ether group is preferable, and an ethylenically unsaturated bond-containing group is more preferable. Specific examples of the group including an aromatic carboxy group represented by Ar¹ include a group represented by Formula (Ar-11), a group represented by Formula (Ar-12), and a group represented by Formula (Ar-13).

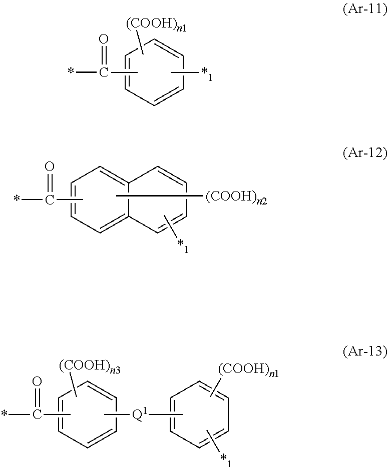

In Formula (Ar-11), n1 represents an integer of 1 to 4, and is preferably 1 or 2 and more preferably 2.

In Formula (Ar-12), n2 represents an integer of 1 to 8, and is preferably an integer of 1 or 4, more preferably 1 or 2, and still more preferably 2.

In Formula (Ar-13), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-13), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formulae (Ar-11) to (Ar-13), *1 represents a bonding position with L¹.

In Formula (Ac-1), L¹ represents —COO— or —CONH—, preferably —COO—.

In Formula (Ac-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by -L^{2a}-O—. Examples of L²a include an alkylene group; an arylene group; a group formed by a combination of an alkylene group and an arylene group; and a group formed by a combination of at least one selected from an alkylene group or an arylene group; and at least one selected from —O—, —CO—, —COO—, —OCO—, —NH—, or —S—, and an alkylene group is preferable. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxy group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L12-2).

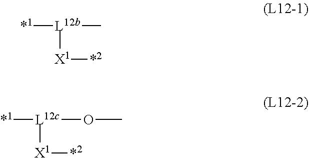

In Formula (L12-1), L^{12b} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12b} include a hydrocarbon group; and a group formed by a combination of a hydrocarbon group and at least one selected from —O—, —CO—, —COO—, —OCO—, —NH—, or —S—, and a hydrocarbon group or a group in which a hydrocarbon group and —O— are combined is preferable.

In Formula (L12-2), L^{12c} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12c} include a hydrocarbon group; and a group formed by a combination of a hydrocarbon group and at least one selected from —O—, —CO—, —COO—, —OCO—, —NH—, or —S—, and a hydrocarbon group is preferable.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20,000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxy group is a resin having the repeating unit represented by Formula (Ac-2), this resin is preferably used as a dispersant.

The polymer chain represented by P¹⁰ may include a polymerizable group. Examples of the polymerizable group include an ethylenically unsaturated bond-containing group and a cyclic ether group.

As the resin, it is also preferable to use a resin having a structure represented by Formula (P-3-1). This resin is preferably used as a dispersant.

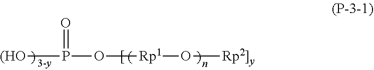

In Formula (P-3-1), Rp¹ represents an alkylene group, Rp² represents a hydrogen atom or a substituent, n represents a number of 10 to 1,000, and y represents a number of 1 or 2.

The alkylene group represented by Rp¹ preferably has 1 to 10 carbon atoms, more preferably has 1 to 5 carbon atoms, and still more preferably has 2 or 3 carbon atoms. Rp¹ is preferably an ethylene group.

Examples of the substituent represented by Rp² include an alkyl group, an aryl group, and a heteroaryl group, and an alkyl group is preferable. The alkyl group preferably has 5 to 30 carbon atoms. The alkyl group may be linear, branched, or cyclic, and is preferably linear or branched and more preferably branched.

A weight-average molecular weight of the resin having the structure represented by Formula (P-3-1) is preferably 2,000 to 50,000, more preferably 3,000 to 45,000, and still more preferably 4,000 to 40,000.

An acid value of the resin having the structure represented by Formula (P-3-1) is preferably 10 to 200 mgKOH/g, more preferably 20 to 150 mgKOH/g, and still more preferably 30 to 120 mgKOH/g.

The photosensitive composition according to the embodiment of the present invention preferably contains a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol % or more in a case where the total amount of the acid group and the basic group is 100 mol %. Examples of the acid group included in the acidic dispersant (acidic resin) include a carboxy group, a sulfo group, and a phosphoric acid group, and a carboxy group is preferable. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

The resin used as the dispersant is also preferably a resin having an ethylenically unsaturated bond-containing group. A C═C value (ethylenically unsaturated bond-containing group value) of the resin having an ethylenically unsaturated bond-containing group is preferably 0.01 to 2.0 mmol/g, more preferably 0.1 to 1.5 mmol/g, and still more preferably 0.1 to 1.0 mmol/g. From the viewpoint of developability and dispersibility of the pigment, it is also preferable that the resin having an ethylenically unsaturated bond-containing group further has an acid group.

As the dispersant, a resin described in JP2018-087939A, block copolymers (EB-1) to (EB-9) described in paragraph Nos. 0219 to 0221 of JP6432077B, polyethyleneimine having a polyester side chain, described in WO2016/104803A, a block copolymer described in WO2019/125940A, a block polymer having an acrylamide structural unit, described in JP2020-066687A, a block polymer having an acrylamide structural unit, described in JP2020-066688A, a dispersant described in WO2016/104803A, or the like can also be used.

A commercially available product is also available as the dispersant, and specific examples thereof include DISPERBYK series (for example, DISPERBYK-111, 161, 2001, and the like) manufactured by BYK-Chemie Japan K.K., Solsperse series (for example, Solsperse 20000, 76500, and the like) manufactured by Lubrizol Corporation, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

A content of the resin in the total solid content of the photosensitive composition is preferably 5% to 50% by mass. The upper limit thereof is preferably 40% by mass or less and more preferably 30% by mass or less. The lower limit thereof is preferably 10% by mass or more and more preferably 20% by mass or more.

In addition, a content of the dispersant is preferably 1 to 100 parts by mass with respect to 100 parts by mass of the colorant. The lower limit thereof is preferably 5 parts by mass or more, more preferably 10 parts by mass or more, and still more preferably 15 parts by mass or more. The upper limit thereof is preferably 50 parts by mass or less, more preferably 40 parts by mass or less, and still more preferably 30 parts by mass or less.

In addition, the content of the dispersant is preferably 50 to 1500 parts by mass with respect to 100 parts by mass of the pigment derivative. The lower limit is preferably 100 parts by mass or more. The upper limit is preferably 1000 parts by mass or less and more preferably 500 parts by mass or less.

The photosensitive composition according to the embodiment of the present invention may contain one kind of resin or two or more kinds of resins. In a case of containing two or more kinds of resins, it is preferable that the total amount thereof is within the above-described range.

### <<Polymerizable Monomer>>

The photosensitive composition according to the embodiment of the present invention preferably contains a polymerizable monomer. The polymerizable monomer is preferably, for example, a compound having an ethylenically unsaturated bond-containing group. Examples of the ethylenically unsaturated bond-containing group include a vinyl group, a (meth)allyl group, and a (meth)acryloyl group. The polymerizable monomer used in the present invention is preferably a radically polymerizable monomer.

A molecular weight of the polymerizable monomer is preferably 100 to 3000. The upper limit is more preferably 2000 or less and still more preferably 1500 or less. The lower limit is more preferably 150 or more and still more preferably 250 or more.

The polymerizable monomer is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable monomer is preferably a 3- to 15-functional (meth)acrylate compound and more preferably a 3- to 6-functional (meth)acrylate compound. Specific examples of the polymerizable monomer include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable monomer, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable monomer, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, AI-600, and LINC-202UA (manufactured by KYOEISHA CHEMICAL Co., LTD.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable monomer, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable monomer, a compound having an acid group can also be used. Examples of the acid group include a carboxy group, a sulfo group, and a phosphoric acid group, and a carboxy group is preferable. Examples of a commercially available product of the polymerizable monomer having an acid group include ARONIX M-510 and M-520, and ARONIX TO-2349 (manufactured by TOAGOSEI CO., LTD). The acid value of the polymerizable monomer having an acid group is preferably 0.1 to 40 mgKOH/g and more preferably 5 to 30 mgKOH/g.

As the polymerizable monomer, a compound having a caprolactone structure can also be used. Examples of a commercially available product of the polymerizable monomer having a caprolactone structure include KAYARAD DPCA-20, DPCA-30, DPCA-60, and DPCA-120 (all manufactured by Nippon Kayaku Co., Ltd.).

As the polymerizable monomer, a polymerizable monomer having an alkyleneoxy group can also be used. The polymerizable monomer having an alkyleneoxy group is preferably a polymerizable monomer having an ethyleneoxy group and/or a propyleneoxy group, more preferably a polymerizable monomer having an ethyleneoxy group, and still more preferably a trifunctional to hexafunctional (meth)acrylate compound having 4 to 20 ethyleneoxy groups. Examples of a commercially available product of the polymerizable monomer having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable monomer, a polymerizable monomer having a fluorene skeleton can also be used. Examples of a commercially available product of the polymerizable monomer having a fluorene skeleton include OGSOL EA-0200 and EA-0300 (manufactured by Osaka Gas Chemicals Co., Ltd., a (meth)acrylate monomer having a fluorene skeleton).

As the polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

A content of the polymerizable monomer in the total solid content of the photosensitive composition is preferably 0.1% to 50% by mass. The lower limit thereof is preferably 0.5% by mass or more, more preferably 1% by mass or more, and still more preferably 5% by mass or more. The upper limit thereof is preferably 40% by mass or less, more preferably 30% by mass or less, still more preferably 30% by mass or less, even more preferably 20% by mass or less, and even still more preferably 15% by mass or less. The polymerizable monomer may be used alone or in combination of two or more kinds thereof. In a case where two or more kinds thereof are used, the total amount thereof is preferably within the above-described range.

### <<Photopolymerization Initiator>>

The photosensitive composition according to the embodiment of the present invention preferably contains a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole compound, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a hexaarylbiimidazole compound, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, peroxide initiators described in JP2019-167313A, aminoacetophenone-based initiators described in JP2020-055992A, oxime-based photopolymerization initiators described in JP2013-190459A, polymers described in JP2020-172619A, and the compound represented by Formula 1 described in WO2020/152120A, the contents of which are incorporated herein by reference.

Specific examples of the hexaarylbiimidazole compound include 2,2′,4-tris(2-chlorophenyl)-5-(3,4-dimethoxyphenyl)-4,5-diphenyl-1,1′-biimidazole.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, compounds described in WO2013/167515A, compounds described in JP5430746B, and compounds described in JP5647738B. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, 2-ethoxycarbonyloxyimino-1-phenylpropane-1-one, and 1-[4-(phenylthio)phenyl]-3-cyclohexyl-propane-1,2-dione-2-(O-acetyloxime). Examples of a commercially available product thereof include Irgacure OXE01, Irgacure OXE02, Irgacure OXE03, and Irgacure OXE04 (all of which are manufactured by BASF SE), TR-PBG-304 and TR-PBG-327 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, compounds described in JP6636081B, and compounds described in KR10-2016-0109444A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

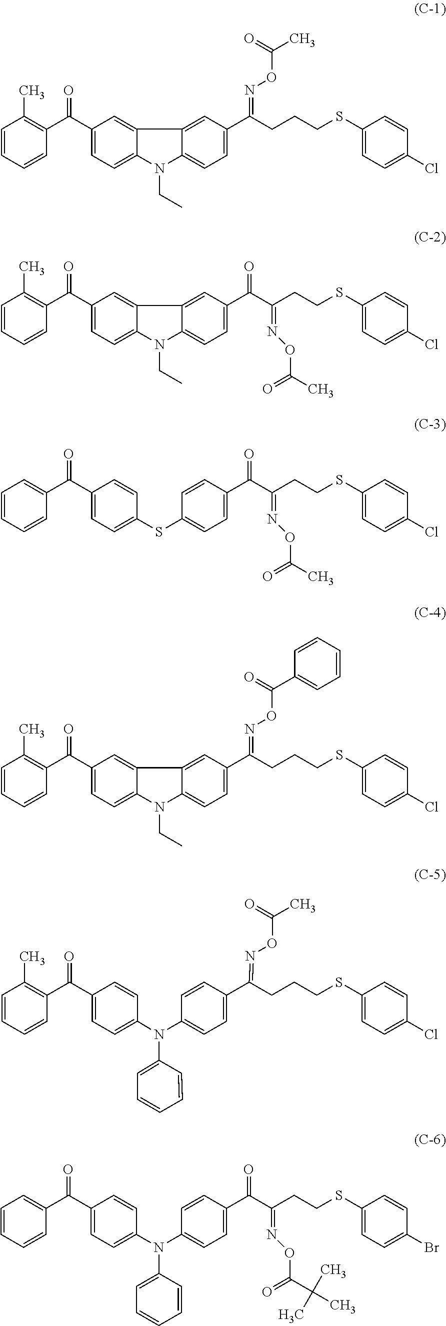 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(N(c2ccccc2)c2ccc(C(=O)c3ccccc3)cc2)cc1]

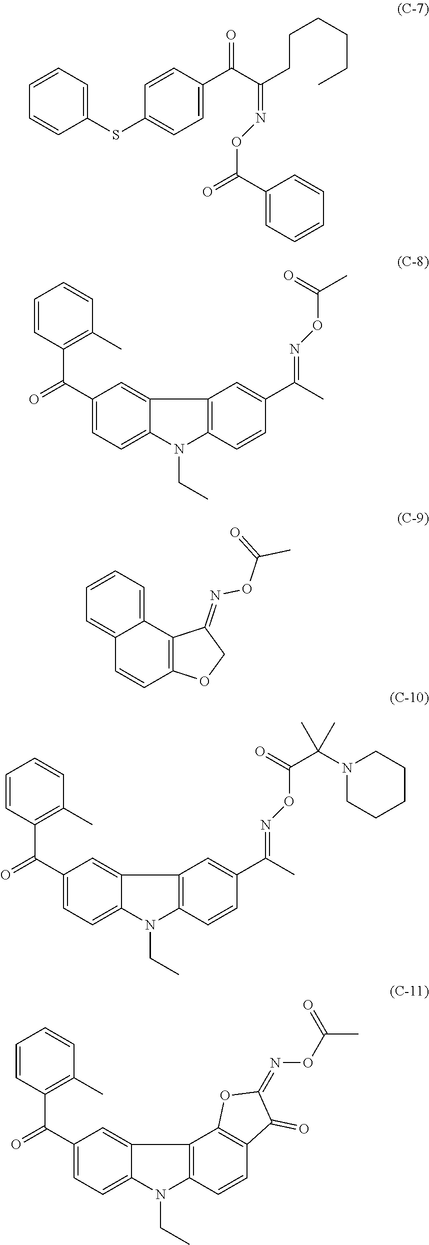

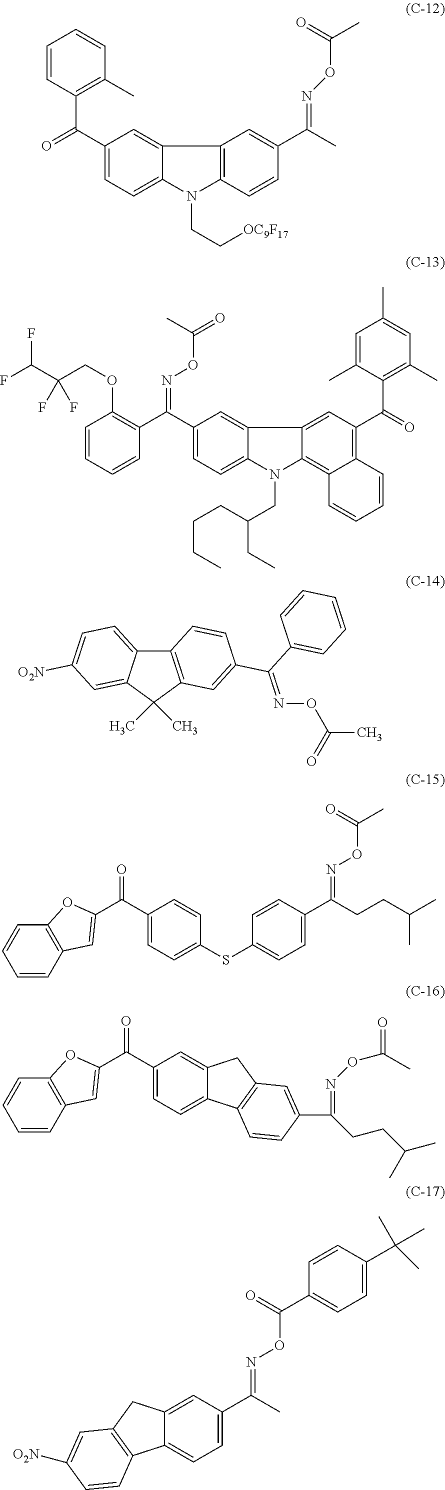

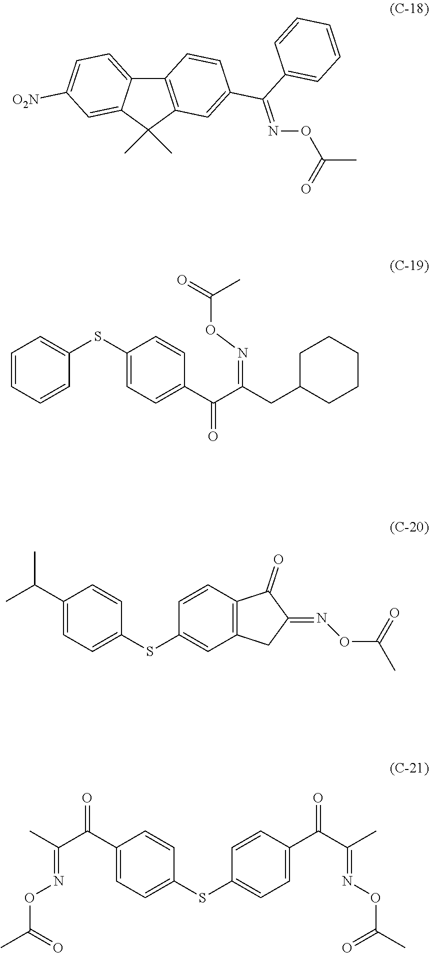

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian) using an ethyl acetate solvent at a concentration of 0.01 g/L.

As the photopolymerization initiator, it is also preferable to use Irgacure OXE01 (manufactured by BASF) and/or Irgacure OXE02 (manufactured by BASF) and Omnirad 2959 (manufactured by IGM Resins B.V.) in combination.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the photosensitive composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A content of the photopolymerization initiator in the total solid content of the photosensitive composition is preferably 0.1% to 30% by mass. The lower limit thereof is preferably 0.5% by mass or more and more preferably 1% by mass or more. The upper limit thereof is preferably 20% by mass or less, more preferably 15% by mass or less, still more preferably 10% by mass or less, even more preferably 7.5% by mass or less, and even still more preferably 5% by mass or less. The photopolymerization initiator may be used alone or in a combination of two or more kinds thereof. In a case where two or more kinds thereof are used, the total amount thereof is preferably within the above-described range.

### <<Solvent>>

The photosensitive composition according to the embodiment of the present invention preferably contains a solvent. Examples of the solvent include an organic solvent. Basically, the type of the solvent is not particularly limited as long as it satisfies solubility of the respective components or coating properties of the composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, 3-pentanone, 4-heptanone, cyclohexanone, 2-methylcyclohexanone, 3-methylcyclohexanone, 4-methylcyclohexanone, cycloheptanone, cyclooctanone, cyclohexyl acetate, cyclopentanone, ethylcarbitol acetate, butylcarbitol acetate, propylene glycol monomethyl ether, propylene glycol monomethyl ether acetate, 3-methoxy-N,N-dimethylpropanamide, 3-butoxy-N,N-dimethylpropanamide, propylene glycol diacetate, 3-methoxybutanol, methyl ethyl ketone, γ-butyrolactone, sulfolane, anisole, 1,4-diacetoxybutane, diethylene glycol monoethyl ether acetate, butane diacetate-1,3-diyl, dipropylene glycol methyl ether acetate, diacetone alcohol (also known as diacetone alcohol or 4-hydroxy-4-methyl-2-pentanone), 2-methoxypropyl acetate, 2-methoxy-1-propanol, and isopropyl alcohol. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore diameter of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the photosensitive composition is preferably 10% to 95% by mass. The upper limit is preferably 92.5% by mass or less and more preferably 90% by mass or less. From the viewpoint of application properties, the lower limit is preferably 20% by mass or more, more preferably 50% by mass or more, still more preferably 75% by mass or more, even more preferably 80% by mass or more, and particularly preferably 85% by mass or more.

In addition, from the viewpoint of environmental regulation, it is preferable that the photosensitive composition according to the embodiment of the present invention does not substantially contain environmentally regulated substances. In the present invention, the description “does not substantially contain environmentally regulated substances” means that the content of the environmentally regulated substances in the photosensitive composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the photosensitive composition, and may be incorporated into the photosensitive composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, photosensitive composition produced by mixing these compounds, or the like.

### <<Compound Having Cyclic Ether Group>>

The photosensitive composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”).

The compound having a cyclic ether group may be a low-molecular-weight compound (for example, having a molecular weight of less than 1,000) or a high-molecular-weight compound (macromolecule) (for example, having a molecular weight of 1,000 or more, and in a case of a polymer, having a weight-average molecular weight of 1,000 or more). The weight-average molecular weight of the cyclic ether group is preferably 200 to 100,000 and more preferably 500 to 50,000. The upper limit of the weight-average molecular weight is preferably 10000 or less, more preferably 5000 or less, and still more preferably 3000 or less.

As the compound having a cyclic ether group, the compounds described in paragraph Nos. 0034 to 0036 of JP2013-011869A, the compounds described in paragraph Nos. 0147 to 0156 of JP2014-043556A, the compounds paragraph Nos. 0085 to 0092 of JP2014-089408A, and the compounds described in JP2017-179172A can also be used.

Examples of a commercially available product of the compound having a cyclic ether group include DENACOL EX-212L, EX-212, EX-214L, EX-214, EX-216L, EX-216, EX-321L, EX-321, EX-850L, and EX-850 (all of which are manufactured by Nagase ChemteX Corporation); ADEKA RESIN EP-4000S, EP-4003S, EP-4010S, and EP-4011S (all of which are manufactured by ADEKA Corporation); NC-2000, NC-3000, NC-7300, XD-1000, EPPN-501, and EPPN-502 (all of which are manufactured by ADEKA Corporation); CELLOXIDE 2021P, CELLOXIDE 2081, CELLOXIDE 2083, CELLOXIDE 2085, EHPE3150, EPOLEAD PB 3600, and PB 4700 (all of which are manufactured by Daicel Corporation); CYCLOMER P ACA 200M, ACA 230AA, ACA Z250, ACA Z251, ACA Z300, and ACA Z320 (all of which are manufactured by Daicel Corporation); jER 1031S, jER 157S65, jER 152, jER 154, and jER 157S70 (all of which are manufactured by Mitsubishi Chemical Corporation); ARON OXETANE OXT-121, OXT-221, OX-SQ, and PNOX (all of which are manufactured by TOAGOSEI CO., LTD.); ADEKA GLYCILOL ED-505 (manufactured by ADEKA Corporation, epoxy group-containing monomer); MARPROOF G-0150M, G-0105SA, G-0130SP, G-0250SP, G-1005S, G-1005SA, G-1010S, G-2050M, G-01100, and G-01758 (manufactured by NOF Corporation, epoxy group-containing polymer); OXT-101, OXT-121, OXT-212, and OXT-221 (all of which are manufactured by TOAGOSEI CO., LTD., oxetanyl group-containing monomer); OXE-10 and OXE-30 (both of which are manufactured by OSAKA ORGANIC CHEMICAL INDUSTRY LTD., oxetanyl group-containing monomer); and BATG (manufactured by SHOWA DENKO K.K.).

A content of the compound having a cyclic ether group in the total solid content of the photosensitive composition is preferably 0.1% to 20% by mass. The lower limit is preferably 0.5% by mass or more and more preferably 1% by mass or more. The upper limit thereof is preferably 15% by mass or less and more preferably 10% by mass or less. The compound having a cyclic ether group may be used alone or in combination of two or more kinds thereof. In a case where two or more kinds thereof are used, the total amount thereof is preferably within the above-described range.

### <<Curing Accelerator>>

The photosensitive composition according to the embodiment of the present invention may contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 0080 of JP2012-150180A, alkoxysilane compounds having an epoxy group described in JP2011-253054A, compounds described in paragraph Nos. 0085 to 0092 of JP5765059B, and carboxy group-containing epoxy curing agent described in JP2017-036379A. In a case of containing a curing accelerator, a content of the curing accelerator in the total solid content of the photosensitive composition is preferably 0.3% to 8.9% by mass and more preferably 0.8% to 6.4% by mass.

### <<Ultraviolet Absorber>>

The photosensitive composition according to the embodiment of the present invention can contain an ultraviolet absorber. Examples of the ultraviolet absorber include a conjugated diene compound, an aminodiene compound, a salicylate compound, a benzophenone compound, a benzotriazole compound, an acrylonitrile compound, a hydroxyphenyltriazine compound, an indole compound, and a triazine compound. Specific examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd.), Tinuvin series and Uvinul series manufactured by BASF SE, and Sumisorb series manufactured by Sumika Chemtex Co., Ltd. In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B, compounds described in paragraph Nos. 0059 to 0076 of WO2016/181987A, and thioaryl group-substituted benzotriazole type ultraviolet absorbers described in WO2020/137819A can also be used. A content of the ultraviolet absorber in the total solid content of the photosensitive composition is preferably 0.01% to 10% by mass and more preferably 0.01% to 5% by mass. The ultraviolet absorber may be used alone or in combination of two or more kinds thereof. In a case where two or more kinds thereof are used, the total amount thereof is preferably within the above-described range.

### <<Polymerization Inhibitor>>

The photosensitive composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. In a case of containing a polymerization inhibitor, a content of the polymerization inhibitor in the total solid content of the photosensitive composition is preferably 0.0001% to 5% by mass. The polymerization inhibitor may be used alone or in combination of two or more kinds thereof. In a case of two or more kinds thereof, the total amount thereof is preferably within the above-described range.

### <<Silane Coupling Agent>>

The photosensitive composition according to the embodiment of the present invention can contain a silane coupling agent. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), 7-aminopropyl trimethoxysilane (trade name: KBM-903, manufactured by Shin-Etsu Chemical Co., Ltd.), 7-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference. A content of the silane coupling agent in the total solid content of the photosensitive composition is preferably 0.01% to 15.0% by mass and more preferably 0.05% to 10.0% by mass. The silane coupling agent may be used alone or in combination of two or more kinds thereof. In a case of two or more kinds thereof, the total amount thereof is preferably within the above-described range.

### <<Surfactant>>

The photosensitive composition according to the embodiment of the present invention can contain a surfactant. As the surfactant, various surfactants such as a fluorine-based surfactant, a nonionic surfactant, a cationic surfactant, an anionic surfactant, or a silicone-based surfactant can be used. The surfactant is preferably a silicone-based surfactant or a fluorine-based surfactant. Examples of the surfactant include surfactants described in paragraph Nos. 0238 to 0245 of WO2015/166779A and surfactants described in JP2020-008634A, the contents of which are incorporated herein by reference.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the photosensitive composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-01, R-40, R-40-LM, R-41, R-41-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FL, 710FM, 710FS, and FTX-218 (manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

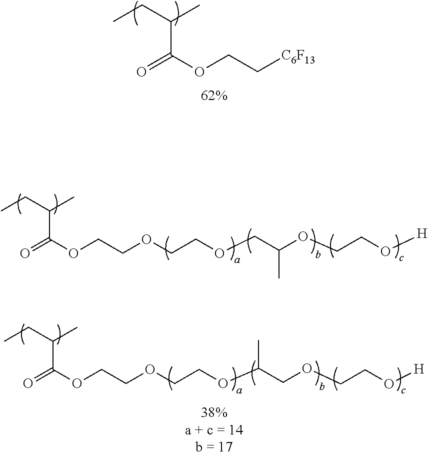

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

In addition, from the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

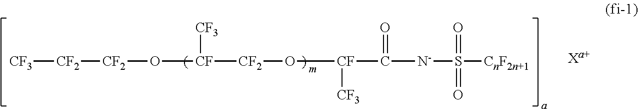

In Formula (fi-1), m represents 1 or 2, n represents an integer of 1 to 4, a represents 1 or 2, and X^{a+} represents an a-valent metal ion, a primary ammonium ion, a secondary ammonium ion, a tertiary ammonium ion, a quaternary ammonium ion, or NH₄⁺.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include: DC3PA, SH7PA, DC11PA, SH21PA, SH28PA, SH29PA, SH30PA, SH8400, SH 8400 FLUID, FZ-2122, 67 Additive, 74 Additive, M Additive, and SF 8419 OIL (all of which are manufactured by Dow-TORAY); TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-333, BYK-3760, and BYK-UV3510 (all of which are manufactured by BYK Chemie). In addition, as the silicone-based surfactant, a compound having the following structure can also be used.

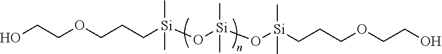

A content of the surfactant in the total solid content of the photosensitive composition is preferably 0.001% by mass to 5.0% by mass and more preferably 0.005% to 3.0% by mass. The surfactant may be used alone or in combination of two or more kinds thereof. In a case of two or more kinds thereof, the total amount thereof is preferably within the above-described range.

### <<Antioxidant>>

The photosensitive composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. A content of the antioxidant in the total solid content of the photosensitive composition is preferably 0.01% to 20% by mass and more preferably 0.3% to 15% by mass. In a case of containing the antioxidant, the antioxidant may be used alone or in combination of two or more kinds thereof. In a case of using two or more kinds thereof, the total amount thereof is preferably within the above-described range.

### <<Other Components>>

Optionally, the photosensitive composition according to the embodiment of the present invention may further contain a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, as desired, the photosensitive composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, the photosensitive composition according to the embodiment of the present invention may contain an aromatic group-containing phosphonium salt described in JP2020-079833A.

In order to adjust the refractive index of a film to be obtained, the photosensitive composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The photosensitive composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

From the viewpoint of environmental regulation, the use of perfluoroalkyl sulfonic acid and a salt thereof and use of perfluoroalkyl carboxylic acid and a salt thereof may be restricted. In the photosensitive composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably in a range of 0.05 ppb to 500 ppb, and still more preferably in a range of 0.1 ppb to 300 ppb with respect to the total solid content of the photosensitive composition. The photosensitive composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The photosensitive composition according to the embodiment of the present invention may include the perfluoroalkyl sulfonic acid and a salt thereof and the perfluoroalkyl carboxylic acid and a salt thereof within the maximum allowable range.

The moisture content in the photosensitive composition according to the embodiment of the present invention is usually 3% by mass or less, preferably 0.01% to 1.5% by mass and more preferably in a range of 0.1% to 1.0% by mass. The moisture content can be measured by a Karl Fischer method.

The photosensitive composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a cone plate-type viscometer.

### <<Storage Container>>

A storage container for the photosensitive composition is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include containers described in JP2015-123351A.

### <Method for Preparing Photosensitive Composition>

The photosensitive composition according to the embodiment of the present invention can be prepared by mixing the above-described components with each other. In the preparation of the photosensitive composition, all the components may be dissolved and/or dispersed at the same time in a solvent to prepare the photosensitive composition, or the respective components may be appropriately left in two or more solutions or dispersion liquids and mixed to prepare the photosensitive composition upon use (during coating), as desired.

In addition, in the preparation of the photosensitive composition, a process for dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A. As the beads used for the dispersion, zirconia, agate, quartz, titania, tungsten carbide, silicon nitride, alumina, stainless steel, glass, or a combination thereof can be used. In addition, an inorganic compound having a Mohs hardness of 2 or more can be used. The above-described may be contained in the composition in an amount of 1 to 10,000 ppm.

It is preferable that, in the preparation of the photosensitive composition, the photosensitive composition is filtered through a filter for the purpose of removing foreign matters, reducing defects, or the like. As the filter, any filters that have been used in the related art for filtration use and the like may be used without particular limitation. Examples of a material of the filter include: a fluororesin such as polytetrafluoroethylene (PTFE) and polyvinylidene fluoride (PVDF); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore diameter of the filter is preferably 0.01 to 7.0 μm, more preferably 0.01 to 3.0 μm, and still more preferably 0.05 to 0.5 μm. In a case where the pore diameter of the filter is within the above-described range, fine foreign matters can be reliably removed. With regard to the pore diameter value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha, Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. In this case, the filtration with each of the filters may be performed once or may be performed twice or more times. In addition, filters having different pore diameters within the above-described range may be combined. In addition, the filtration through the first filter may be performed with only a dispersion liquid, the other components may be mixed therewith, and then the filtration through the second filter may be performed.

### <Film>

The film according to the embodiment of the present invention is a film obtained from the above-described photosensitive composition according to the embodiment of the present invention. The film according to the embodiment of the present invention can be used for a color filter. More specifically, the film according to the embodiment of the present invention can be preferably used for a blue pixel of the color filter. A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 m or more, more preferably 0.2 μm or more, and still more preferably 0.3 μm or more.

### <Color Filter>

The color filter according to the embodiment of the present invention has the above-described film according to the embodiment of the present invention. The color filter according to the embodiment of the present invention preferably includes the film according to the embodiment of the present invention as a colored pixel of the color filter, and more preferably includes the film according to the embodiment of the present invention as a blue pixel. It is preferable that the color filter according to the embodiment of the present invention further includes a colored pixel selected from a red pixel, a green pixel, a cyan pixel, or a yellow pixel. Examples of one aspect of the color filter according to the embodiment of the present invention include a color filter including a blue pixel formed of the film according to the embodiment of the present invention, a green pixel, and a red pixel.

The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, a thickness of the film can be appropriately adjusted depending on the purposes. The film thickness is preferably 5 μm or less, more preferably 1 μm or less, and still more preferably 0.6 μm or less. The lower limit of the film thickness is preferably 0.1 μm or more, more preferably 0.2 μm or more, and still more preferably 0.3 μm or more.

A width of the pixel included in the color filter is preferably 0.2 to 10.0 μm. The lower limit thereof is preferably 0.4 μm or more, more preferably 0.5 μm or more, and still more preferably 0.6 μm or more. The upper limit thereof is preferably 5.0 μm or less, more preferably 2.0 μm or less, still more preferably 1.0 μm or less, and even more preferably 0.8 μm or less. In addition, the Young's modulus of the pixel is preferably 0.5 to 20 GPa and more preferably 2.5 to 15 GPa.

Each pixel included in the color filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 500 to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured, for example, using an ultra-high resistance meter 5410 (manufactured by Advantest Corporation).

In the color filter, a protective layer may be provided on a surface of the pixel. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The color filter may have a structure in which each pixel is embedded in a space partitioned in, for example, a lattice form by a partition wall.

### <Method for Manufacturing Color Filter>

Next, a method for manufacturing a color filter using the photosensitive composition according to the embodiment of the present invention will be described. The method for manufacturing a color filter preferably includes a step of forming a photosensitive composition layer on a support using the above-described photosensitive composition according to the embodiment of the present invention, a step of exposing the photosensitive composition layer in a patterned manner, and a step of removing a non-exposed portion of the photosensitive composition layer by development to form a pattern (pixel). A step (pre-baking step) of baking the photosensitive composition layer and a step (post-baking step) of baking the developed pattern (pixel) may be provided, as desired.

In the step of forming a photosensitive composition layer, the photosensitive composition layer is formed on a support using the photosensitive composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate.

As a method of applying the photosensitive composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the photosensitive composition, reference can be made to the description in WO2017/030174A and WO2017/018419A, the contents of which are incorporated herein by reference.

The photosensitive composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the photosensitive composition layer is exposed in a patterned manner (exposing step). For example, the photosensitive composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, a non-exposed portion of the photosensitive composition layer is removed by development to form a pattern (pixel). The removal of the non-exposed portion of the photosensitive composition layer by development can be carried out using a developer. Thus, the photosensitive composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. Examples of the surfactant include the surfactants described above. Among these, a nonionic surfactant is preferable. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the photosensitive composition layer after development while rotating the support on which the photosensitive composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

### <Solid-State Imaging Element>

A solid-state imaging element according to an embodiment of the present invention has the film according to the embodiment of the present invention. The configuration of the solid-state imaging element is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. The partition wall in this case preferably has a low refractive index for each colored pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

### <Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### Examples

Hereinafter, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below. iPr in the structural formulae shown below represents an isopropyl group.

### <Production of Miniaturization Pigment>

100 parts by mass of a pigment shown in the table below, 1,200 parts by mass of sodium chloride, and 120 parts by mass of diethylene glycol were charged into a 1-gallon stainless steel kneader (manufactured by INOUE MFG., INC.) and kneaded at 60° C. for 4 hours. The obtained kneading composition was put into 3000 parts by mass of warm water and stirred for 1 hour to form a slurry, and the slurry was filtered and washed with water repeatedly to remove sodium chloride and diethylene glycol, and dried at 80° C. for 24 hours to obtain a miniaturization pigment shown in the following table.

TABLE 2

| Miniaturization pigment | | |
|---|---|---|
| | Average primary particle | |
| Type | diameter (μm) | Type of pigment as raw material |
| Pig-1 | 0.03 | C.I. Pigment Blue 15:6 (blue pigment) |
| Pig-2 | 0.04 | C.I. Pigment Blue 15:3 (blue pigment) |
| Pig-3 | 0.05 | C.I. Pigment Blue 15:4 (blue pigment) |
| Pig-4 | 0.01 | C.I. Pigment Blue 16 (blue pigment) |
| Pig-5 | 0.04 | C.I. Pigment Violet 23 (violet pigment) |

### <Production of Dispersion Liquid>

A mixed solution obtained by mixing raw materials shown in the following tables was mixed and dispersed for 3 hours using a beads mill (zirconia beads having a diameter of 0.1 mm). Next, using a high-pressure disperser (NANO-3000-10, manufactured by Nippon BEE Chemical Co., Ltd.) equipped with a pressure reducing mechanism, the dispersion liquid was dispersed under a pressure of 2000 kg/cm² at a flow rate of 500 g/min. The dispersion treatment was repeated a total of 10 times to produce each dispersion liquid.

| | Miniaturization pigment | | | | Pigment derivative | | | | |
|---|---|---|---|---|---|---|---|---|---|
| Dispersion | Type | Part by | Type | Part by | Type | Part by | Type | Part by | Type |
| liquid | 1 | mass | 2 | mass | 1 | mass | 2 | mass | 3 |
| BB-1 | Pig-1 | 7.1 | Pig-5 | 2.4 | Syn-3 | 0.6 | Syn-1 | 1.4 | Syn-2 |
| BB-2 | Pig-2 | 7.1 | Pig-5 | 2.4 | Syn-3 | 0.6 | Syn-1 | 1.4 | Syn-2 |
| BB-3 | Pig-3 | 7.1 | Pig-6 | 2.4 | Syn-3 | 0.6 | Syn-1 | 1.4 | Syn-2 |
| BB-4 | Pig-4 | 7.1 | Pig-5 | 2.4 | Syn-3 | 0.6 | Syn-1 | 1.4 | Syn-2 |
| BB-5 | Pig-1 | 7.0 | Pig-5 | 2.5 | Syn-3 | 0.6 | Syn-1 | 1.5 | Syn-2 |
| BB-6 | Pig-1 | 6.9 | Pig-5 | 2.6 | Syn-3 | 0.6 | Syn-1 | 1.7 | Syn-2 |
| BB-7 | Pig-1 | 9.0 | | | Syn-3 | 0.8 | Syn-1 | 2.0 | |
| BB-8 | Pig-1 | 7.1 | Pig-6 | 2.4 | Syn-4 | 0.6 | Syn-1 | 1.4 | Syn-2 |
| BB-9 | Pig-1 | 7.1 | Pig-6 | 2.4 | Syn-5 | 0.6 | Syn-1 | 1.4 | Syn-2 |
| BB-10 | Pig-1 | 7.1 | Pig-5 | 2.4 | Syn-6 | 0.6 | Syn-1 | 1.4 | Syn-2 |
| BB-11 | Pig-1 | 7.1 | Pig-6 | 2.4 | Syn-7 | 0.6 | Syn-1 | 1.4 | Syn-2 |
| BB-12 | Pig-1 | 7.1 | Pig-6 | 2.4 | Syn-3 | 0.6 | Syn-4 | 0.6 | Syn-2 |
| BB-c1 | Pig-1 | 7.1 | Pip-5 | 2.4 | Syn-1 | 0.9 | Syn-2 | 1.4 | |
| BB-c2 | Pig-1 | 7.1 | Pig-6 | 2.4 | Syn-6 | 0.9 | Syn-7 | 1.4 | |
| | Pigment | | | | | | | | |
| | derivative | Dispersant | | | | Solvent | | | |
| Dispersion | Part by | Type | Part by | Type | Part by | Type | Part by | Type | Part by |
| liquid | mass | 1 | mass | 2 | mass | 1 | mass | 2 | mass |
| BB-1 | 0.4 | D-1 | 4.1 | | | S-1 | 58.8 | S-2 | 25.2 |
| BB-2 | 0.4 | D-1 | 3.7 | D-2 | 0.4 | S-1 | 58.8 | S-3 | 25.2 |
| BB-3 | 0.4 | D-1 | 4.1 | | | S-1 | 58.8 | S-2 | 25.2 |
| BB-4 | 0.4 | D-1 | 3.7 | D-2 | 0.4 | S-1 | 58.8 | S-2 | 25.2 |
| BB-5 | 0.2 | D-3 | 4.1 | | | S-1 | 58.8 | S-3 | 25.2 |
| BB-6 | 0.1 | D-1 | 4.1 | | | S-1 | 58.8 | S-3 | 25.2 |
| BB-7 | | D-1 | 4.1 | | | S-1 | 58.8 | S-3 | 25.2 |
| BB-8 | 0.4 | D-4 | 4.1 | | | S-1 | 58.8 | S-2 | 25.2 |
| BB-9 | 0.4 | D-1 | 4.1 | | | S-1 | 58.8 | S-2 | 25.2 |
| BB-10 | 0.4 | D-1 | 4.1 | | | S-1 | 58.8 | S-2 | 25.2 |
| BB-11 | 0.4 | D-1 | 4.1 | | | S-1 | 58.8 | S-2 | 25.2 |
| BB-12 | 1.2 | D-1 | 4.1 | | | S-1 | 58.8 | S-2 | 25.2 |
| BB-c1 | | D-1 | 4.1 | | | S-1 | 58.8 | S-2 | 25.2 |
| BB-c2 | | D-1 | 4.1 | | | S-1 | 58.8 | S-2 | 25.2 |

Details of materials represented by an abbreviation described above are as follows.

### (Miniaturization Pigment)

Pig-1 to Pig-5: miniaturization pigments Pig-1 to Pig-5 described above

### (Pigment Derivative)

Syn-1: compound having the following structure (blue pigment derivative; maximum value of a molar absorption coefficient in a wavelength range of 400 to 700 nm was 10,000 L·mol⁻¹·cm⁻¹ or more)

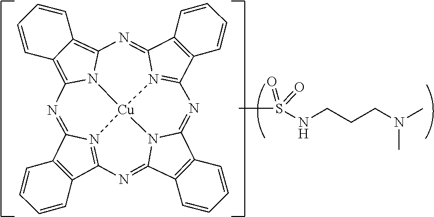

Syn-2: compound having the following structure (violet pigment derivative; maximum value of a molar absorption coefficient in a wavelength range of 400 to 700 nm was 10,000 L·mol⁻¹·cm⁻¹ or more)

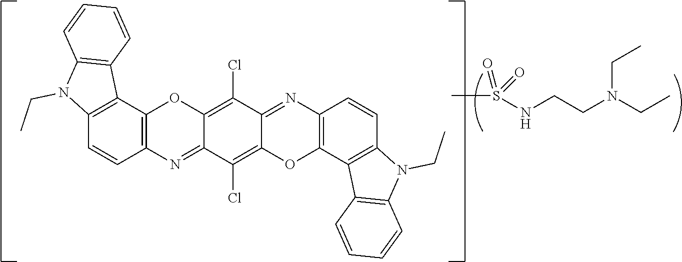

Syn-3: compound having the following structure (transparent pigment derivative; maximum value of a molar absorption coefficient in a wavelength range of 400 to 700 nm was 3,000 L·mol⁻¹·cm⁻¹ or less)

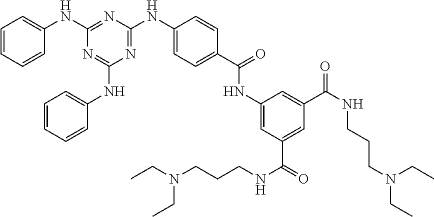 [SMILES: CCN(CC)CCCNC(=O)c1cc(NC(=O)c2ccc(Nc3nc(Nc4ccccc4)nc(Nc4ccccc4)n3)cc2)cc(C(=O)NCCCN(CC)CC)c1]

Syn-4: compound having the following structure (transparent pigment derivative; maximum value of a molar absorption coefficient in a wavelength range of 400 to 700 nm was 3,000 L·mol⁻¹·cm⁻¹ or less)

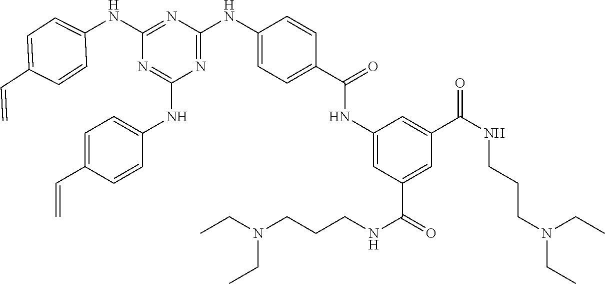 [SMILES: C=Cc1ccc(Nc2nc(Nc3ccc(C=C)cc3)nc(Nc3ccc(C(=O)Nc4cc(C(=O)NCCCN(CC)CC)cc(C(=O)NCCCN(CC)CC)c4)cc3)n2)cc1]

Syn-5: compound having the following structure (transparent pigment derivative; maximum value of a molar absorption coefficient in a wavelength range of 400 to 700 nm was 3,000 L·mol⁻¹·cm⁻¹ or less)

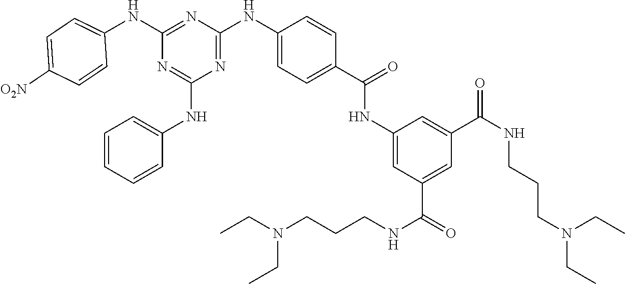 [SMILES: CCN(CC)CCCNC(=O)c1cc(NC(=O)c2ccc(Nc3nc(Nc4ccccc4)nc(Nc4ccc([N+](=O)[O-])cc4)n3)cc2)cc(C(=O)NCCCN(CC)CC)c1]

Syn-6: compound having the following structure (transparent pigment derivative; maximum value of a molar absorption coefficient in a wavelength range of 400 to 700 nm was 3,000 L·mol⁻¹·cm⁻¹ or less)

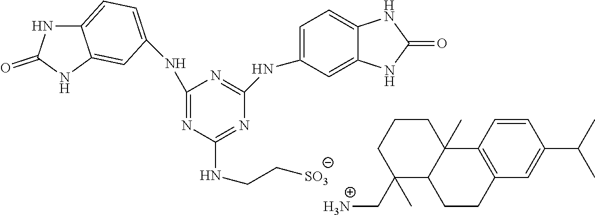

Syn-7: compound having the following structure (transparent pigment derivative; maximum value of a molar absorption coefficient in a wavelength range of 400 to 700 nm was 3,000 L·mol⁻¹·cm⁻¹ or less)

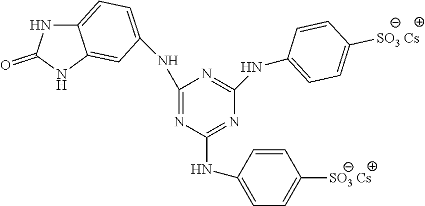

### (Dispersant)

D-1: resin having the following structure (weight-average molecular weight: 20,000; numerical value described together with the main chain indicates a molar ratio, and the numerical value described together with the side chain indicates the number of repeating units)

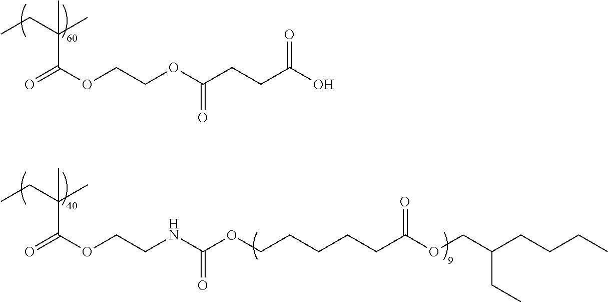

D-2: resin having the following structure (weight-average molecular weight: 800)

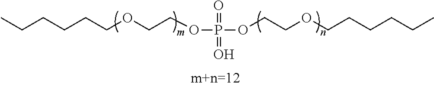

D-3: resin having the following structure (weight-average molecular weight: 15,000; numerical value described together with the main chain indicates a molar ratio, and the numerical value described together with the side chain indicates the number of repeating units)

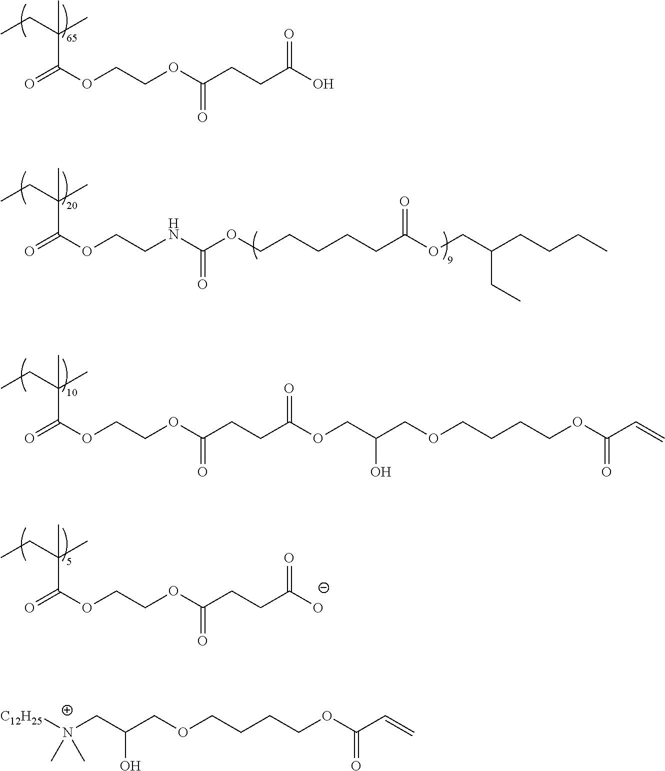

D-4: resin shown below (weight-average molecular weight: 8,000, acid value: 37 mgKOH/g, ethylenically unsaturated bond-containing group value: 0.22 mmol/g)

TABLE 4

| | Constitutional unit 1 | | Constitutional unit 2 | | Constitutional unit 3 | |
|---|---|---|---|---|---|---|
| | Type | Molar ratio | Type | Molar ratio | Type | Molar ratio |
| D-4 | 1-A | 5 | 2-A | 87 | 3-A | 8 |

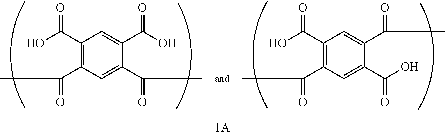

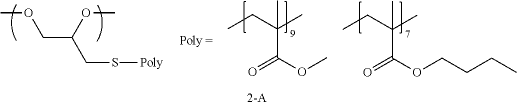

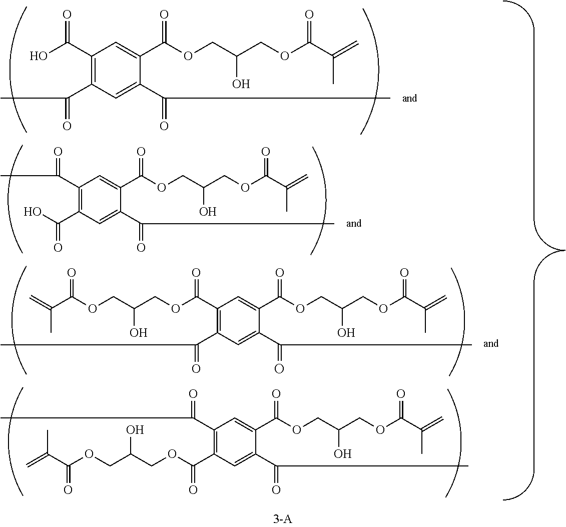

### (Solvent)

S-1: propylene glycol monomethyl ether acetate (PGMEA)
S-2: cyclopentanone
S-3: cyclohexanone

### <Production of Photosensitive Composition>

Raw materials shown in the following tables were mixed and stirred, and the obtained mixture was filtered using a nylon filter (manufactured by Nihon Pall Corporation) having a pore diameter of 0.45 μm to produce a photosensitive composition. The unit of the numerical value described in the column of the blending amount is part by mass. In addition, the total content of the colorant and the pigment derivative in the total solid content of each photosensitive composition is described in the column of “Total content of colorant and pigment derivative”.

| | Dispersion | | | | | | Polymerizable | |
|---|---|---|---|---|---|---|---|---|
| | liquid | | Dye | | Resin | | monomer | |
| | | Blending | | Blending | | Blending | | Blending |
| | Type | amount | Type | amount | Type | amount | Type | amount |
| Example | BB-1 | 65.0 | — | — | B-1 | 1.0 | M-1 | 2.0 |
| 1 | | | | | | | M-2 | 2.0 |
| Example | BB-2 | 65.0 | — | — | B-1 | 1.0 | M-1 | 2.0 |
| 2 | | | | | | | M-2 | 2.0 |
| Example | BB-3 | 65.0 | — | — | B-1 | 1.0 | M-1 | 2.0 |
| 3 | | | | | | | M-2 | 2.0 |
| Example | BB-4 | 65.0 | — | — | B-1 | 1.0 | M-1 | 2.0 |
| 4 | | | | | | | M-2 | 2.0 |
| Example | BB-5 | 65.0 | — | — | B-1 | 1.0 | M-1 | 2.0 |
| 5 | | | | | | | M-2 | 2.0 |
| Example | BB-6 | 65.0 | — | — | B-1 | 1.0 | M-1 | 2.0 |
| 6 | | | | | | | M-2 | 2.0 |
| Example | BB-7 | 50.0 | Dye 1 | 6.0 | B-1 | 1.0 | M-1 | 2.0 |
| 7 | | | | | | | M-2 | 2.0 |
| Example | BB-8 | 65.0 | — | — | B-1 | 1.0 | M-1 | 2.0 |
| 8 | | | | | | | M-2 | 2.0 |
| Example | BB-9 | 65.0 | — | — | B-1 | 1.0 | M-1 | 2.0 |
| 9 | | | | | | | M-2 | 2.0 |
| Example | BB-10 | 65.0 | — | — | B-1 | 1.0 | M-1 | 2.0 |
| 10 | | | | | | | M-2 | 2.0 |
| | | | | | | | | Total |
| | | Photo- | | | | | | content of |
| | | polymerization | | | | | | colorant and |
| | | initiator | | Surfactant | | Solvent | | pigment |
| | | | Blending | | Blending | | Blending | derivative |
| | | Type | amount | Type | amount | Type | amount | (% by mass) |

| | | | | | | | |
|---|---|---|---|---|---|---|---|
| Example | I-1 | 0.80 | W-1 | 0.02 | S-1 | 29.18 | 47.7 |
| 1 | | | | | | | |
| Example | I-1 | 0.72 | W-1 | 0.02 | S-1 | 29.18 | 47.7 |
| 2 | I-2 | 0.08 | | | | | |
| Example | I-3 | 0.80 | W-1 | 0.02 | S-1 | 29.18 | 47.7 |
| 3 | | | | | | | |
| Example | I-1 | 0.64 | W.1 | 0.02 | S-1 | 29.18 | 47.7 |
| 4 | I-2 | 0.16 | | | | | |
| Example | I-1 | 0.80 | W-1 | 0.02 | S-1 | 29.18 | 47.7 |
| 5 | | | | | | | |
| Example | I-1 | 0.80 | W-1 | 0.02 | S-1 | 29.18 | 47.7 |
| 6 | | | | | | | |
| Example | I-1 | 0.72 | W-1 | 0.02 | S-1 | 38.18 | 60.3 |
| 7 | I-2 | 0.08 | | | | | |
| Example | I-1 | 0.72 | W-1 | 0.02 | S-1 | 29.18 | 47.7 |
| 8 | I-2 | 0.08 | | | | | |
| Example | I-1 | 0.72 | W-1 | 0.02 | S-1 | 29.18 | 47.7 |
| 9 | I-2 | 0.08 | | | | | |
| Example | I-1 | 0.72 | W-1 | 0.02 | S-1 | 29.18 | 47.7 |
| 10 | I-2 | 0.08 | | | | | |

| | Dispersion | | | | | | Polymerizable | |
|---|---|---|---|---|---|---|---|---|
| | liquid | | Dye | | Resin | | monomer | |
| | | Blending | | Blending | | Blendin | | Blending |
| | Type | amount | Type | amount | Type | amount | Type | amount |
| Example 11 | BB-11 | 65.0 | — | — | B-1 | 1.0 | M-1 | 2.0 |
| | | | | | | | M-2 | 2.0 |
| Example 12 | BB-12 | 65.0 | — | — | B-1 | 1.0 | M-1 | 2.0 |
| | | | | | | | M-2 | 2.0 |
| Comparative | BB-c1 | 65.0 | — | — | B-1 | 1.0 | M-1 | 2.0 |
| Example 1 | | | | | | | M-2 | 2.0 |
| Comparative | BB-c2 | 65.0 | — | — | B-1 | 1.0 | M-1 | 2.0 |
| Example 2 | | | | | | | M-2 | 2.0 |

| | | | | | | | Total |
|---|---|---|---|---|---|---|---|
| | | | | | | | content |
| | Photo- | | | | | | of colorant |
| | polymerization | | | | | | and pigment |
| | initiator | | Surfactant | | Solvent | | derivative |
| | | Blending | | Blending | | Blending | (% by |
| | Type | amount | Type | amount | Type | amount | mass) |
| Example 11 | I-1 | 0.72 | W-1 | 0.02 | S-1 | 29.18 | 47.7 |
| | I-2 | 0.08 | | | | | |
| Example 12 | I-1 | 0.72 | W-1 | 0.02 | S-1 | 29.18 | 47.7 |
| | I-2 | 0.08 | | | | | |
| Comparative | I-1 | 0.72 | W-1 | 0.02 | S-1 | 29.18 | 47.7 |
| Example 1 | I-2 | 0.08 | | | | | |
| Comparative | I-1 | 0.72 | W-1 | 0.02 | S-1 | 29.18 | 47.7 |
| Example 2 | I-2 | 0.08 | | | | | |

Details of materials represented by an abbreviation described above are as follows.

### (Dispersion Liquid)

BB-1 to BB-12, BB-c1, BB-c2: dispersion liquids BB-1 to BB-12, BB-c1, and BB-c2 described above

### (Dye)

Dye 1: dye having the following structure (xanthene dye, weight-average molecular weight: 9,000)

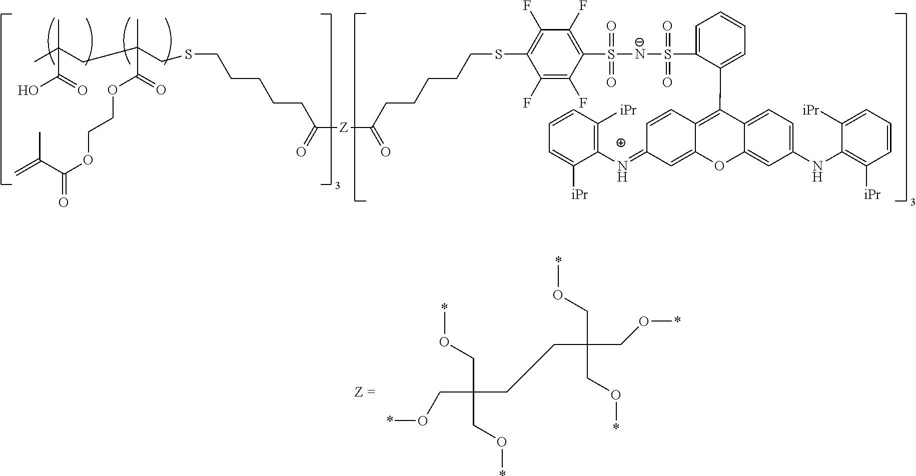

### (Resin)

B-1: compound having the following structure (weight-average molecular weight: 11,000; numerical value described together with the main chain indicates a molar ratio)

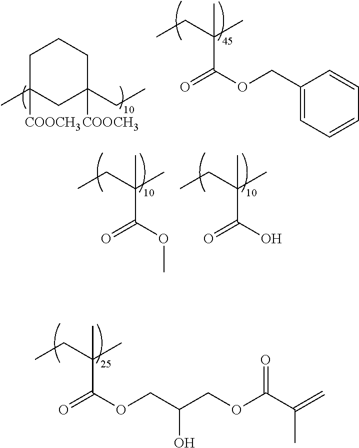

### (Polymerizable Monomer)

M-1: compound having the following structure

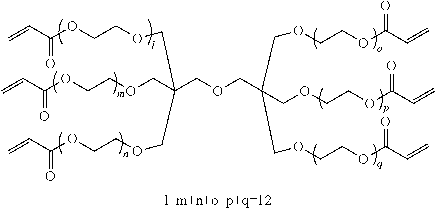

M-2: mixture of compounds having the following structures (mixture in which a molar ratio of a compound on the left (hexafunctional (meth)acrylate compound) and a compound on the right (pentafuctional (meth)acrylate compound) was 7:3)

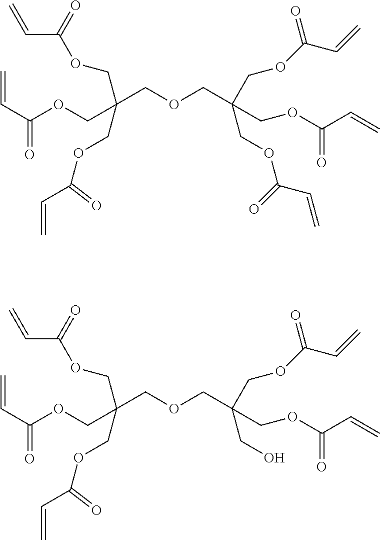

### (Photopolymerization Initiator)

I-1: compound having the following structure

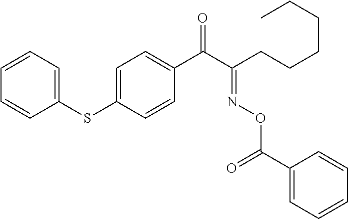 [SMILES: CCCCCC/C(=N\OC(=O)c1ccccc1)C(=O)c1ccc(Sc2ccccc2)cc1]

I-2: compound having the following structure

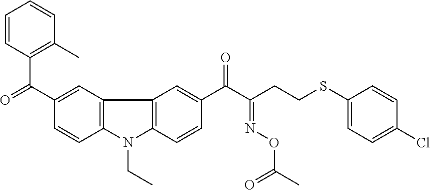 [SMILES: CCn1c2ccc(C(=O)/C(CCSc3ccc(Cl)cc3)=N/OC(C)=O)cc2c2cc(C(=O)c3ccccc3C)ccc21]

I-3: compound having the following structure

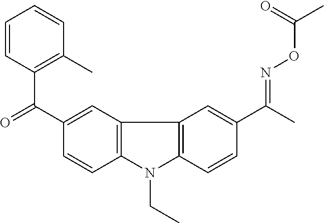 [SMILES: CCn1c2ccc(C(=O)c3ccccc3C)cc2c2cc(/C(C)=N/OC(C)=O)ccc21]

### (Surfactant)

W-1: KF-6000 (silicone-based surfactant, manufactured by Shin-Etsu Chemical Co., Ltd.)

### (Solvent)

S-1: propylene glycol monomethyl ether acetate

### <Evaluation of Light Resistance>

A 5 cm×5 cm glass substrate was coated with the photosensitive composition obtained as described above using a spin coater so that the thickness of a film after drying was 0.6 μm, and pre-baking was performed using a hot plate at 100° C. for 120 seconds to obtain a monochromatic color filter for evaluation of light resistance. A SiO₂ layer having a thickness of 100 nm was formed on the color filter by a chemical vapor deposition method. For the purpose of cutting off light of 380 nm or less, a sharp cut filter (L38, manufactured by HOYA Corporation) was placed on the obtained monochromatic color filter for evaluation of light resistance, and the obtained monochromatic color filter for evaluation of light resistance was irradiated with light of a xenon lamp at 100,000 lux for 20 hours (equivalent to 2,000,000 lux×h). A color difference (ΔE*ab value) of the monochromatic color filter before and after the irradiation with a xenon lamp was measured, and the light resistance was evaluated according to the following standard. It can be said that, as the ΔE*ab value is smaller, the light resistance is more excellent.
A: ΔE*ab value was less than 3.
B: ΔE*ab value was 3 or more and less than 10.
C: ΔE*ab value was 10 or more.

### <Evaluation of Moisture Resistance>

A 5 cm×5 cm glass substrate was coated with the photosensitive composition obtained as described above by a spin coating method so that the thickness of a film after drying was 0.6 μm, and pre-baking was performed using a hot plate at 100° C. for 120 seconds to obtain a monochromatic color filter for evaluation of moisture resistance. A SiN layer having a thickness of 500 nm was formed on the color filter by a chemical vapor deposition method. The obtained monochromatic color filter for evaluation of moisture resistance was allowed to stand in an environment of 130° C. and a humidity of 85% for 96 hours. A color difference (ΔE*ab value) of the color filter before and after the standing was measured, and the moisture resistance was evaluated according to the following standard. It can be said that, as the ΔE*ab value is smaller, the moisture resistance is more excellent.
A: ΔE*ab value was less than 3.
B: ΔE*ab value was 3 or more and less than 10.
C: ΔE*ab value was 10 or more.

### <Evaluation of Storage Stability>

A viscosity of the photosensitive composition obtained as described above was measured using an E-type viscometer (manufactured by TOKI SANGYO CO., LTD., RE-85L) under the condition of 25° C. Thereafter, the photosensitive composition was left to stand under the conditions of 45° C. and 3 days, and then the viscosity thereof was measured again. A rate of change in viscosity of the photosensitive composition before and after the standing was calculated, and the storage stability was evaluated according to the following evaluation standard. It can be said that, as the numerical value of the rate of change in viscosity is smaller, the storage stability is better. The viscosity of the photosensitive composition was measured in a state in which the temperature was adjusted to 25° C. The evaluation standard is as follows, and the evaluation results are shown in the table below.

Rate of change in viscosity (%)=(|Viscosity of photosensitive composition after standing at 45° C. for 3 days−Viscosity of photosensitive composition immediately after production|/Viscosity of photosensitive composition immediately after production)×100
A: rate of change in viscosity was less than 10%.
B: rate of change in viscosity was 10% or more and less than 50%.
C: rate of change in viscosity was 50% or more.

TABLE 7

| | Light | Moisture | Storage |
|---|---|---|---|
| | resistance | resistance | stability |
| Example 1 | A | A | A |
| Example 2 | A | A | A |
| Example 3 | A | A | A |
| Example 4 | A | A | A |
| Example 5 | A | A | A |
| Example 6 | A | A | A |
| Example 7 | A | A | A |
| Example 8 | A | A | A |
| Example 9 | A | A | A |
| Example 10 | A | A | A |
| Example 11 | A | A | A |
| Example 12 | A | A | B |
| Comparative | B | C | A |
| Example 1 | | | |
| Comparative | C | A | A |
| Example 2 | | | |

As shown in the above table, in Examples, the evaluations of the light resistance and the moisture resistance were better than those in Comparative Examples.

In Example 12, in a case where the amounts of the dispersion liquid and the resin added were changed and the total content of the colorant and the pigment derivative in the total solid content was changed to 45% by mass or 50% by mass, the same results were obtained.

What is claimed is:

1. A photosensitive composition comprising:
a colorant A including a pigment;
a pigment derivative B; and
a resin C,
wherein the colorant A includes a blue pigment,
the pigment derivative B includes a transparent pigment derivative B1 and a chromatic pigment derivative B2, and
a total content of the colorant A and the pigment derivative B in a total solid content of the photosensitive composition is 40% by mass or more.

2. The photosensitive composition according to claim 1,
wherein a maximum value of a molar absorption coefficient of the pigment derivative B1 in a wavelength range of 400 to 700 nm is 3,000 L·mol⁻¹·cm⁻¹ or less.

3. The photosensitive composition according to claim 1,
wherein a maximum value of a molar absorption coefficient of the pigment derivative B2 in a wavelength range of 400 to 700 nm is 10,000 L·mol⁻¹·cm⁻¹ or more.

4. The photosensitive composition according to claim 1,
wherein the pigment derivative B1 is a compound having a triazine ring.

5. The photosensitive composition according to claim 1,
wherein the pigment derivative B1 is a compound including a group represented by Formula (A1), 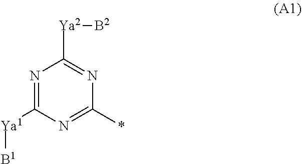
in Formula (A1), * represents a bonding site,
Ya¹ and Ya² each independently represent —N(Ra¹)- or —O—, where Ra¹ represents a hydrogen atom, an alkyl group, an alkenyl group, an alkynyl group, or an aryl group, and
B¹ and B^{z} each independently represent a hydrogen atom or a substituent.

6. The photosensitive composition according to claim 1,
wherein the pigment derivative B2 is a phthalocyanine compound.

7. The photosensitive composition according to claim 1,
wherein a maximal absorption wavelength of the pigment derivative B2 is in a wavelength range of 400 to 700 nm.

8. The photosensitive composition according to claim 1,
wherein the blue pigment is a phthalocyanine compound.

9. The photosensitive composition according to claim 1,
wherein the colorant A includes the blue pigment and a violet pigment.

10. The photosensitive composition according to claim 1, further comprising:
a polymerizable monomer; and
a photopolymerization initiator.

11. The photosensitive composition according to claim 1,
wherein, in a case where a film having a film thickness of 1 μm is formed of the photosensitive composition, an average value of a transmittance of the film in a thickness direction to light in a wavelength range of 400 to 500 nm is 55% or more, an average value of a transmittance of the film in the thickness direction to light in a wavelength range of 600 to 700 nm is 20% or less, and a wavelength at which a transmittance is 50% is in a wavelength range of 450 to 550 nm.

12. The photosensitive composition according to claim 1,
wherein the photosensitive composition is a photosensitive composition for forming a blue pixel.

13. A film obtained from the photosensitive composition according to claim 1.

14. A color filter comprising:
the film according to claim 13.

15. A solid-state imaging element comprising:
the film according to claim 13.

16. An image display device comprising:
the film according to claim 13.
